(19) United States
(12) Patent Application Publication
(10) Pub. No.: US 2025/0234742 A1
(43) Pub. Date: Jul. 17, 2025

(54) DISPLAY SUBSTRATE, METHOD OF MANUFACTURING THE SAME, AND DISPLAY DEVICE

(71) Applicants: YUNNAN INVENSIGHT OPTOELECTRONICS TECHNOLOGY CO., LTD., Kunming (CN); BOE TECHNOLOGY GROUP CO., LTD., Beijing (CN)

(72) Inventors: Zhijian Zhu, Beijing (CN); Qingshan Shan, Beijing (CN); Pengcheng Lu, Beijing (CN); Xiaochuan Chen, Beijing (CN); Fengxian Tian, Beijing (CN); Shengji Yang, Beijing (CN)

(21) Appl. No.: 18/703,679

(22) PCT Filed: Mar. 31, 2023
(86) PCT No.: PCT/CN2023/085369

§ 371 Date: Apr. 22, 2024

(51) Int. Cl. H10K 59/38; H10K 59/12; H10K 59/80

(52) U.S. Cl. CPC H10K 59/38; H10K 59/1201; H10K 59/873; H10K 59/879

(57) ABSTRACT

Provided is a display substrate, including: a base substrate, and a light emitting functional layer, a color resist layer; and a first planarization layer sequentially arranged on the base substrate. The light emitting functional layer includes light emitting devices, which include a first light emitting device. The color resists include a first color resist, a refractive index of which is greater than that of the first planarization layer, and different color resists allow light of different colors to pass through. The first color resist includes a first light transmitting portion, a surface of which on a side close to the first planarization layer includes a first curved surface recessed towards the base substrate, and an orthographic projection of the first light emitting device on the base substrate falls within an orthographic projection of the first light transmitting portion on the base substrate.

### CROSS-REFERENCE TO RELATED APPLICATION

This application is a Section 371 National Stage Application of International Application No. PCT/CN2023/085369, filed on Mar. 31, 2023, entitled “DISPLAY SUBSTRATE, METHOD OF MANUFACTURING THE SAME, AND DISPLAY DEVICE”, incorporated herein by reference in its entirety.

### TECHNICAL FIELD

The present disclosure relates to the field of display technology, and specifically to a display substrate, a method of manufacturing the same, and a display device.

### BACKGROUND

Micro displays have broad marketing and application prospects, and may be especially suitable for helmet displays, stereoscopic display mirrors, and eye-type displays, etc. Micro displays are in an interdisciplinary field of microelectronics and optoelectronics, which involves a wide range of technologies including optoelectronics, microelectronics, electronic informatics, and optics, etc. and is a technical field that involves a plurality of disciplines such as physics, chemistry, materials science, and electronics. A silicon-based OLED micro display that combines organic light emitting diode (OLED) technology and complementary metal oxide semiconductor (CMOS) technology is a cross integrated product of an optoelectronics industry and a microelectronics industry, which may promote development of new-generation micro displays, and also promote research and development of organic electronics on silicon or even molecular electronics on silicon.

### SUMMARY

The present disclosure provides a display substrate, a method of manufacturing the same, and a display device.

According to a first aspect of the present disclosure, a display substrate is provided, including: a base substrate; a light emitting functional layer provided on the base substrate; a color resist layer provided on a side of the light emitting functional layer away from the base substrate; and a first planarization layer provided on a side of the color resist layer away from the base substrate, where the light emitting functional layer includes a plurality of light emitting devices, and the plurality of light emitting devices include a first light emitting device; where the color resist layer includes a plurality of color resists, different color resists allow light of different colors to pass through, and the plurality of color resists include a first color resist, a refractive index of the first color resist being greater than a refractive index of the first planarization layer; and where the first color resist includes a first light transmitting portion, a surface of the first light transmitting portion on a side close to the first planarization layer includes a first curved surface recessed towards the base substrate, and an orthographic projection of the first light emitting device on the base substrate falls within an orthographic projection of the first light transmitting portion on the base substrate.

According to the embodiments of the present disclosure, the first color resist overlaps with other color resists adjacent to the first color resist, and in a region of an overlap between the first color resist and the other color resists adjacent to the first color resist, the first color resist is on a side of the other color resists away from the base substrate.

According to the embodiments of the present disclosure, the first color resist includes a first edge portion surrounding the first light transmitting portion, a surface of the first edge portion on a side close to the first planarization layer includes a second curved surface recessed towards the base substrate, and a curvature radius of the first curved surface is greater than a curvature radius of the second curved surface.

According to the embodiments of the present disclosure, the other color resists include a second color resist and a third color resist, and the second color resist includes a second light transmitting portion and a second edge portion surrounding the second light transmitting portion; the first edge portion overlaps with the second edge portion, the second edge portion includes a first portion, and the first edge portion is on a side of the first portion of the second edge portion away from the base substrate; and the third color resist is on a side of the second color resist away from the first color resist, and the second edge portion includes a second portion on a side of the third color resist away from the base substrate.

According to the embodiments of the present disclosure, in a direction from the first color resist to the second color resist, an overlap between the first edge portion and the first portion has a first overlapping size; in a direction from the second color resist to the third color resist, an overlap between the second portion and the third color resist has a second overlapping size; and the first overlapping size is greater than or equal to the second overlapping size.

According to the embodiments of the present disclosure, an average thickness of either the second color resist or the third color resist is greater than an average thickness of the first color resist, and a difference between the average thickness of either the second color resist or the third color resist and the average thickness of the first color resist is a first predetermined difference, and a ratio of the first predetermined difference to the average thickness of either the second color resist or the third color resist is less than or equal to 1:5.

According to the embodiments of the present disclosure, the display substrate further includes: a lens layer provided on a side of the first planarization layer away from the base substrate. The lens layer includes a plurality of lenses, and a first gap is formed between two lenses adjacent to each other; and where an orthographic projection of the first gap on the base substrate at least partially overlaps with an orthographic projection of an overlap between color resists adjacent to each other on the base substrate.

According to the embodiments of the present disclosure, the orthographic projection of the first gap on the base substrate covers the orthographic projection of the overlap between the color resists adjacent to each other on the base substrate.

According to the embodiments of the present disclosure, at least one first gap includes a groove recessed towards a center of the lens, the groove includes a first surface on a side away from the base substrate, and the first surface includes a flat surface or a smooth curved surface.

According to the embodiments of the present disclosure, in a first gap, edges of first surfaces adjacent to each other away from the base substrate are spaced apart from each other by a first predetermined spacing, edges of the first surfaces adjacent to each other close to the base substrate are spaced apart from each other by a second predetermined spacing, and the first predetermined spacing is less than the second predetermined spacing.

According to the embodiments of the present disclosure, the first overlapping size is less than the second predetermined spacing.

According to the embodiments of the present disclosure, a spacing between a center of the first curved surface and a surface of the first planarization layer away from the base substrate in a direction perpendicular to the base substrate is greater than or equal to the first predetermined spacing.

According to the embodiments of the present disclosure, the first surface has a first length in a direction from an edge of the first surface away from the base substrate to an edge of the first surface close to the base substrate, and the first length is less than the first predetermined spacing.

According to the embodiments of the present disclosure, the second predetermined spacing is less than a size of at least one lens in a thickness direction of the display substrate.

According to the embodiments of the present disclosure, at least one first surface has a first predetermined angle with the first planarization layer, and the first predetermined angle is an acute angle.

According to the embodiments of the present disclosure, at least one lens is coaxially arranged with the first curved surface and the first light emitting device.

According to the embodiments of the present disclosure, an orthographic projection of at least one lens on the base substrate falls within an orthographic projection of the first curved surface on the base substrate.

According to the embodiments of the present disclosure, a spacing between a center of the first curved surface and a surface of the first planarization layer away from the base substrate in a direction perpendicular to the base substrate is less than or equal to a maximum height of at least one lens.

According to the embodiments of the present disclosure, the first gap includes a third curved surface recessed towards the base substrate on a side close to the base substrate, and a curvature radius of the third curved surface is smaller than a curvature radius of the first curved surface.

According to the embodiments of the present disclosure, the display substrate further include an encapsulation layer between the light emitting functional layer and the color resist layer. The encapsulation layer includes at least one fourth curved surface on a side close to the color resist layer, an orthographic projection of the at least one fourth curved surface on the base substrate at least partially overlaps with an orthographic projection of the first color resist on the base substrate, and the fourth curved surface and the encapsulation layer are configured such that, for incident light incident on the first color resist through the fourth curved surface, a brightness-related viewing angle after the incident light is incident on the first color resist is greater than a brightness-related viewing angle before the incident light is incident on the first color resist.

According to the embodiments of the present disclosure, the fourth curved surface includes a curved surface recessed towards the base substrate, and the refractive index of the first color resist is less than a refractive index of the encapsulation layer; or the fourth curved surface includes a curved surface protruding towards the first planarization layer, and the refractive index of the first color resist is greater than the refractive index of the encapsulation layer.

According to the embodiments of the present disclosure, the orthographic projection of the at least one fourth curved surface on the base substrate falls within an orthographic projection of the first curved surface on the base substrate.

According to the embodiments of the present disclosure, a ratio of a light emission area of the first light emitting device to an area of an orthographic projection of the first curved surface on the base substrate is greater than or equal to 1:2.

According to the embodiments of the present disclosure, in a direction from a center of the first color resist to an edge of the first color resist, a ratio of a size of the first edge portion to a size of the first light transmitting portion is greater than or equal to 1:10.

According to a second aspect of the present disclosure, a method of manufacturing a display substrate is provided, including: forming a base substrate; forming a light emitting functional layer on the base substrate, where the light emitting functional layer includes a plurality of light emitting devices, and the plurality of light emitting devices include a first light emitting device; forming a color resist layer on a side of the light emitting functional layer away from the base substrate, where the color resist layer includes a plurality of color resists, different color resists allow light of different colors to pass through, the plurality of color resists include a first color, a surface of the first color resist on a side away from the base substrate includes a first curved surface recessed towards the base substrate, the first curved surface includes a first light transmitting portion, and an orthographic projection of the first light emitting device on the base substrate falls within an orthographic projection of the first light transmitting portion on the base substrate; and forming a first planarization layer on a side of the color resist layer away from the base substrate, a refractive index of the first color resist being greater than a refractive index of the first planarization layer.

According to the embodiments of the present disclosure, other color resists other than the first color resist in the color resist layer include a second color resist and a third color resist, and the forming a color resist layer on a side of the light emitting functional layer away from the base substrate includes: forming the second color resist and the third color resist on the side of the light emitting functional layer away from the base substrate by using a spin-coating process, where the second color resist and the third color resist adopt a first coating thickness; forming a first color resist material on the side of the light emitting functional layer away from the base substrate; spin-coating the first color resist material to a second coating thickness less than the first coating thickness, where the second coating thickness is configured such that in a process of the spin-coating, the first color resist material between the second color resist and the third color resist forms a first recess, and an edge of the first recess is overlapped on a side of the second color resist away from the base substrate and a side of the third color resist away from the base substrate; and retaining the first recess by exposure and development, so as to obtain the first color resist having the first curved surface.

According to a third aspect of the present disclosure, a display device is provided, including the display substrate mentioned above.

### BRIEF DESCRIPTION OF THE DRAWINGS

The above contents and other objectives, features and advantages of the present disclosure will be more apparent through the following description of the embodiments of the present disclosure with reference to the drawings. In the drawings:

FIG. 1 schematically shows a top view of a display substrate in a comparative example;

FIG. 2 schematically shows a cross-sectional view of FIG. 1 taken along sectional line BB′;

FIG. 3A schematically shows a brightness distribution diagram of red light in an example;

FIG. 3B schematically shows a brightness distribution diagram of green light in an example;

FIG. 4 schematically shows a brightness distribution diagram of blue light in an example;

FIG. 5 schematically shows a top view of a display substrate according to the embodiments of the present disclosure;

FIG. 6 schematically shows a cross-sectional view of FIG. 5 taken along sectional line CC′;

FIG. 7 schematically shows a top view of a plurality of color resists according to the embodiments of the present disclosure;

FIG. 8 schematically shows a diagram of an optical path from a light emitting device to a color resist according to the embodiments of the present disclosure;

FIG. 9 schematically shows a brightness distribution diagram of blue light as a viewing angle varies according to the embodiments of the present disclosure;

FIG. 10 schematically shows a schematic diagram of three color resists overlapping with each other according to the embodiments of the present disclosure;

FIG. 11A to FIG. 11F schematically show schematic diagrams of providing a lens layer according to the embodiments of the present disclosure;

FIG. 12A and FIG. 12B schematically show schematic diagrams of a fourth curved surface of an encapsulation layer according to the embodiments of the present disclosure;

FIG. 13 schematically shows a schematic diagram of forming a microcavity structure according to the embodiments of the present disclosure;

FIG. 14 schematically shows a flowchart of forming a display substrate according to the embodiments of the present disclosure;

FIG. 15 to FIG. 22 schematically show schematic diagrams of stages of a manufacturing process of a display substrate according to the embodiments of the present disclosure;

FIG. 18 to FIG. 20 schematically show schematic diagrams of forming a color resist layer by using spin-coating according to the embodiments of the present disclosure; and

FIG. 23 schematically shows a schematic diagram of a display panel according to the embodiments of the present disclosure.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out any inventive effort fall within the scope of protection of the present disclosure.

It will be noted that in the accompanying drawings, for clarity and/or description purposes, a size and relative size of an element may be enlarged. Accordingly, the size and relative size of each element are not necessarily limited to those shown in the drawings. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, will be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It will be noted that although the terms “first”, “second”, etc. may be used here to describe various components, members, elements, regions, layers and/or portions, these components, members, elements, regions, layers and/or portions will not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, etc. may be used here to describe a relationship between an element or feature and another element or feature as shown in the drawing. It will be understood that the spatial relationship terms are intended to cover other different orientations of a device in use or operation in addition to the orientation described in the drawing. For example, if a device in the drawing is turned upside down, an element or feature described as “below” or “under” another element or feature will be oriented “above” or “on” the another element or feature.

Herein, the terms “substantially”, “about”, “approximately” “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used here includes a stated value and means that a specific value determined by those ordinary skilled in the art is within an acceptable range of deviation. For example, “about” may mean being within one or more standard deviations, or within ±30%, ±20%, ±10% or ±5% of the stated value.

It will be noted that the expression “the same layer” herein refers to a layer structure that is formed by firstly forming, using a same film forming process, a film layer used to form a specific pattern, and then patterning, using an one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art will understand that, unless otherwise specified, the expression “height” or “thickness” herein refers to a size in a direction perpendicular to a surface of each film layer provided on the display substrate, that is, a size in a light emitting direction of the display substrate, or referred to as a size in a normal direction of the display device.

In a comparative example, a silicon-based micro display is provided. A silicon-based micro display is a micro organic light emitting diode display (micro OLED display) with a monocrystalline silicon integrated circuit as a back plate and organic light emitting diodes (OLED) as a light source, which has the advantages of small size, light weight, high contrast, rapid response, and low power consumption, etc. and is expected to become a next-generation mainstream mobile display terminal.

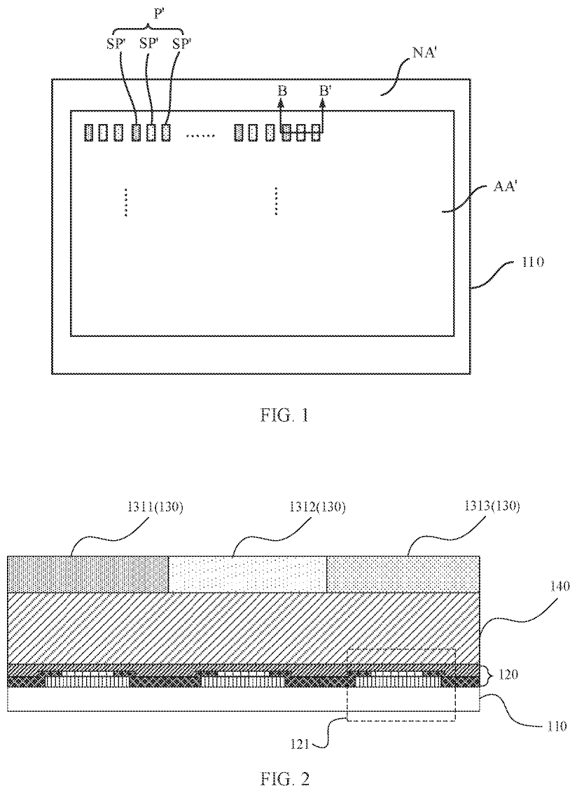

FIG. 1 schematically shows a top view of a display substrate in a comparative example, and FIG. 2 schematically shows a cross-sectional view of FIG. 1 taken along sectional line BB′. Referring to FIG. 1 and FIG. 2, in this comparative example, the display substrate includes a display area AA′ and a peripheral area NA′ surrounding the display area AA′. A plurality of pixel units P′ are arranged in an array in the display area. Each pixel unit P′ includes a plurality of sub-pixels SP′ having different colors. For example, the sub-pixels SP′ in a pixel unit P′ include a red sub-pixel, a green sub-pixel, and a blue sub-pixel. The display substrate further includes a base substrate 110, a light emitting functional layer 120 provided on the base substrate 110, a color resist layer 130 (also known as color filters, CF) provided on a side of the light emitting functional layer 120 away from the base substrate 110, and an encapsulation layer 140 provided between the light emitting functional layer 120 and the color resist layer 130. The light emitting functional layer 120 includes a plurality of light emitting devices 121, which serve as light emitting sources and cooperate with the color resist layer 130 to achieve color display. Specifically, the color resist layer 130 includes a plurality of color resists, and each color resist may absorb light with specific wavelength(s), so that only monochromatic light is allowed to pass through the color resist. For example, the plurality of color resists include a first color resist 1311, a second color resist 1312, and a third color resist 1313. The first color resist 1311 may allow red light to pass through, the second color resist 1312 may allow green light to pass through, and the third color resist 1313 may allow blue light to pass through. In this way, light (such as white light) emitted by a light emitting device 121 may be displayed in red, green or blue after passing through a respective color resist.

Color shift (or chromatic aberration) at different viewing angles and a brightness attenuation trend are important evaluation indicators for a display effect, which are generally characterized by a color shift-related viewing angle and a brightness-related viewing angle. The color shift-related viewing angle may refer to a viewing angle corresponding to an acceptable range of color shift. The brightness-related viewing angle may refer to a viewing angle corresponding to a brightness that is attenuated to a predetermined value (such as 50% of the maximum brightness).

In a silicon-based micro display, due to a microcavity effect and other factors, a particular monochromatic light may have a brightness-related viewing angle significantly smaller than that of other monochromatic lights. Specifically, as the viewing angle increases, a brightness of one of three monochromatic lights, namely red light, green light and blue light, is attenuated significantly faster than that of the other two. As a result, a performance of the silicon-based micro display in terms of the color shift-related viewing angle is poor, that is, unacceptable color shift may occur in a small range of viewing angle.

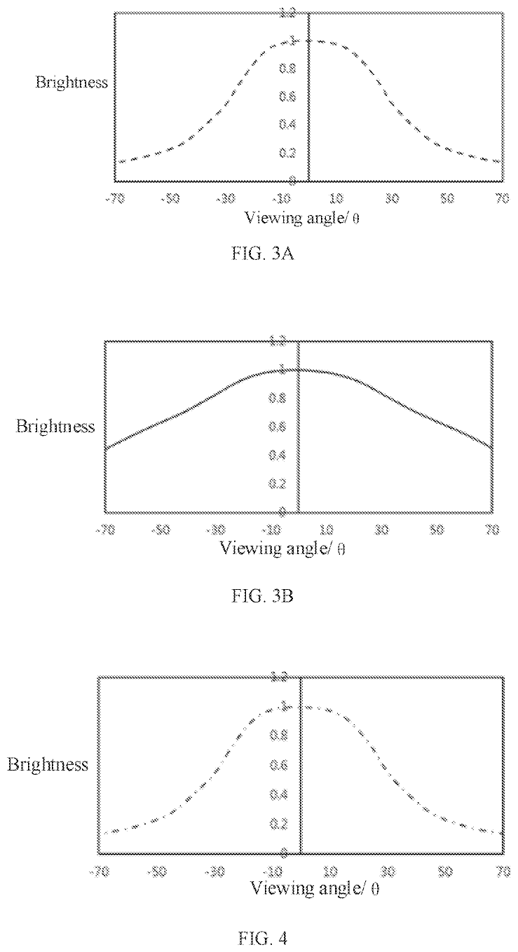

FIG. 3A schematically shows a brightness distribution diagram of red light in an example, FIG. 3B schematically shows a brightness distribution diagram of green light in an example, and FIG. 4 schematically shows a brightness distribution diagram of blue light in an example.

Referring to FIG. 3A to FIG. 4, a brightness of green light is attenuated slow as the viewing angle increases, while a brightness of red light and a brightness of blue light are attenuated fast as the viewing angle increases. Although the brightness of the red light is attenuated fast, in this example, a red sub-pixel and structures related to it, such as a large light emission area of the red sub-pixel, may compensate for this problem to some extent. However, it is difficult to make compensation for the brightness-related viewing angle of a blue sub-pixel. For example, even if the blue sub-pixel has a large light emission area, other factors in the silicon-based micro display may result in a decrease of the brightness-related viewing angle of the blue light (such as the narrowing of the brightness-related viewing angle caused by a blue light gain produced by the microcavity structure). Therefore, the brightness of the blue light may be still attenuated rapidly as the viewing angle increases, leading to the presence of more red light and green light at large viewing angles, and thus a display color is yellowish when compared to an expected color, that is, color shift occurs.

The color shift-related viewing angel is closely related to the display effect. Therefore, how to reduce color shift in the silicon-based micro display has become an urgent technical problem to be solved.

In view of this, the embodiments of the present disclosure provide a display substrate, including: a base substrate, a light emitting functional layer provided on the base substrate, a color resist layer provided on a side of the light emitting functional layer away from the base substrate, and a first planarization layer provided on a side of the color resist layer away from the base substrate. The light emitting functional layer includes a plurality of light emitting devices, and the plurality of light emitting devices include a first light emitting device. The brightness-related viewing angle of the first light emitting device is less than that of other light emitting devices. The color resist layer includes a plurality of color resists, and different color resists allow light of different colors to pass through. The plurality of color resists include a first color resist, and the first color resist has a refractive index greater than the first planarization layer. The first color resist includes a first light transmitting portion, and a surface of the first light transmitting portion on a side close to the first planarization layer includes a first curved surface recessed towards the base substrate. An orthographic projection of the first light emitting device on the base substrate falls within an orthographic projection of the first light transmitting portion on the base substrate.

In the display substrate of the embodiments of the present disclosure, a lens structure is formed using the first curved surface of the first color resist and the first planarization layer. Since the refractive index of the first color resist is greater than that of the first planarization layer, the lens structure serves as an optical concave lens which has a divergence effect on incident light. Therefore, in the embodiments of the present disclosure, the concave lens may be used to perform compensation for the monochromatic light having the small brightness-related viewing angle among the plurality of monochromatic lights, so as to increase the brightness-related viewing angle of that monochromatic light. Compared to the solution in the comparative example, the solution in the embodiments of the present disclosure may improve a small brightness-related viewing angle of a monochromatic light in the silicon-based micro display, so that the color shift under a large viewing angle may be mitigated, thereby increasing the color shift-related viewing angle and improving the display effect.

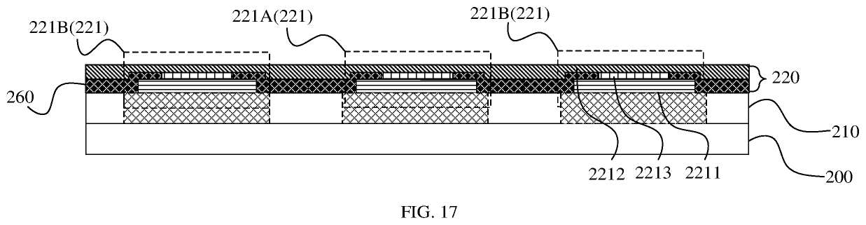

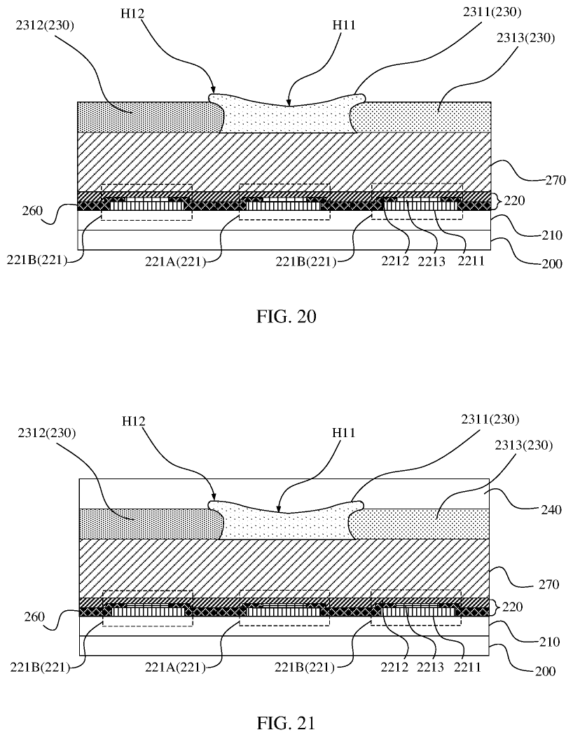

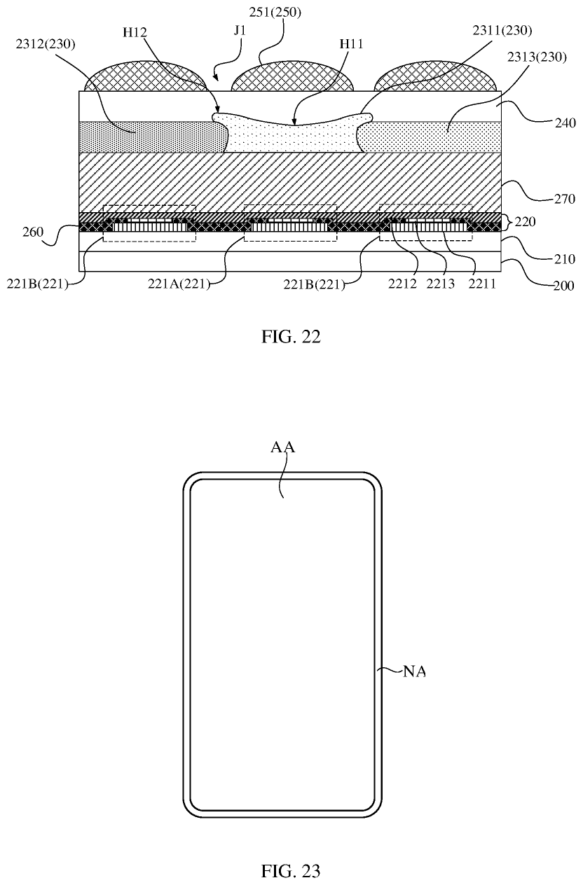

The display substrate according to the embodiments of the present disclosure will be described in detail below with reference to FIG. 5 to FIG. 22.

The embodiments of the present disclosure provide a display substrate. FIG. 5 schematically shows a top view of the display substrate according to the embodiments of the present disclosure.

Referring to FIG. 5, the display substrate according to the embodiments of the present disclosure includes a display area AA and a peripheral area NA located on at least one side of the display area AA. The display substrate may further include a gate driver circuit 11 and a driver chip 12, which are located in the peripheral area NA. For example, the gate driver circuit 11 may be provided on at least one side of the display area AA. In the embodiment shown in FIG. 5, the gate driver circuit 11 is provided on each of a left side and a right side of the display area AA. It will be noted that the left side and the right side may refer to a left side and a right side of the display substrate (screen) viewed by human eyes during display. For example, the driver chip 12 may be provided on at least one side of the display area AA. In the embodiment shown in FIG. 5, the driver chip 12 is provided on a lower side of the display area AA. It will be noted that the lower side may be a lower side of the display substrate (screen) viewed by human eyes during display.

The gate driver circuit 11 may be implemented by a shift register, and the gate driver circuit 11 may provide scanning signals to gate lines (not shown) in the display substrate. The driver chip 12 may provide data signals to data signal lines (not shown) in the display substrate.

It will be noted that FIG. 5 shows the gate driver circuits 11 are located on the left side and the right side of the display area AA, and the driver chip 12 is located on the lower side of the display area AA. However, the embodiments of the present disclosures are not limited to this, and the gate driver circuit 11 and the driver chip may be provided at any suitable position in the peripheral area NA.

For example, a GOA technology, namely gate driver on array, may be adopted for the gate driver circuit 11. In the GOA technology, the gate driver circuit 11 is provided directly on an array substrate to replace an external chip. The driver chip 12 may be folded onto a back side of the display substrate through a chip-on-film and other structures.

Each GOA unit serves as one stage of shift register, and each stage of shift register is connected to one gate line. Scanning signals are sequentially output through stages of shift registers, so as to achieve progressive scanning of pixel units. In some embodiments, each stage of shift register may be connected to a plurality of gate lines. In this way, it may adapt to a development trend of high resolution and narrow bezel of display substrates.

The display substrate further includes a base substrate 200 and a plurality of pixel units P provided on the base substrate 200 and located in the display area AA.

The display substrate in the embodiments of the present disclosure may specifically be a display substrate applied in a silicon-based micro display, that is, the base substrate 200 of the display substrate in the embodiments of the present disclosure may be a silicon-based substrate, which is also known as an IC wafer. Pixel circuits, the gate driver circuits 11 and the driver chip 12, etc. in the display substrate may be directly manufactured on the silicon-based substrate.

Each pixel unit P may include a plurality of sub-pixels. For example, each pixel unit P includes a first sub-pixel SP1, a second sub-pixel SP2, and a third sub-pixel SP3. For sake of understanding, the first sub-pixel SP1, the second sub-pixel SP2 and the third sub-pixel SP3 may be hereinafter described as a blue sub-pixel, a green sub-pixel and a red sub-pixel, respectively. However, this description is not intended to limit colors of light emitted by the first sub-pixel SP1, the second sub-pixel SP2 and the third sub-pixel SP3, but refers to colors of light displayed by the first sub-pixel SP1, the second sub-pixel SP2 and the third sub-pixel SP3 in the display substrate. Specifically, the first sub-pixel SP1, the second sub-pixel SP2 and the third sub-pixel SP3 all emit white light, and the white light emitted by these three are filtered through respective color resists and then colored light is emitted. For example, the white light emitted by the first sub-pixel SP1 passes through a blue color resist and then blue light is emitted, the white light emitted by the second sub-pixel SP2 passes through a red color resist and then red light is emitted, and the white light emitted by the third sub-pixel SP3 passes through a green color resist and then green light is emitted.

It will be noted that FIG. 5 schematically shows that a shape of the sub-pixel is a rectangle. However, the embodiments of the present disclosures are not limited to this. For example, the shape of the sub-pixel may be a pentagon, a hexagon, a circle, or other shapes. Moreover, an arrangement manner of the plurality of sub-pixels of a pixel unit P is not limited to that shown in FIG. 5.

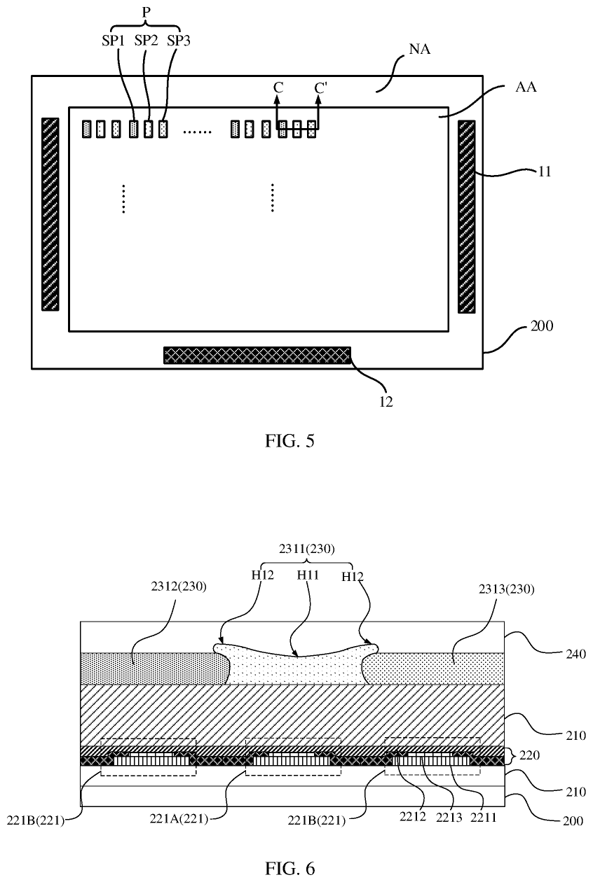

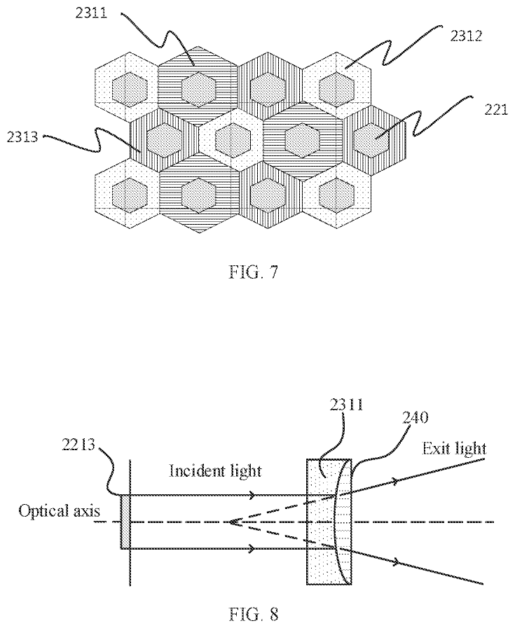

FIG. 6 schematically shows a cross-sectional view of FIG. 5 taken along sectional line CC′.

Referring to FIG. 5 and FIG. 6, in the embodiments of the present disclosure, the display substrate further includes a pixel circuit layer 210 provided on the base substrate 200, a light emitting functional layer 220 provided on a side of the pixel circuit layer 210 away from the base substrate 200, a color resist layer 230 provided on a side of the light emitting functional layer 220 away from the base substrate 200, and a first planarization layer 240 provided on a side of the color resist layer 230 away from the base substrate 200.

In the embodiments of the present disclosure, at least one sub-pixel includes a pixel circuit located in the pixel circuit layer 210 and a light emitting device 221 located in the light emitting functional layer 220. At least one light emitting device 221 includes a first electrode 2211, a second electrode 2212 and a light emitting portion 2213 between the first electrode 2211 and the second electrode 2212, and the three are arranged in a stack. The pixel circuit is electrically connected to one of the first electrode 2211 and the second electrode 2212 to provide a driving current to that electrode, and the other of the first electrode 2211 and the second electrode 2212 is electrically connected to a constant signal terminal, so that the light emitting portion 2213 may generate, in response to the driving current applied to the first electrode 2211, light having a brightness corresponding the driving current.

In the embodiments of the present disclosure, the color resist layer 230 includes a plurality of color resists. For example, the color resist layer 230 includes a red color resist, a green color resist, and a blue color resist. At least one color resist is located on a light exit side of the at least one light emitting device 221, and the color resist is arranged facing the light emitting device. For example, the blue color resist is arranged on the light exit side of the first light emitting device 221A. Accordingly, when the white light emitted by the first sub-pixel SP1 (specifically the light emitting device 221 of the first sub-pixel SP1) passes through the blue color resist, and the light of other colors other than the blue light in the white light may be absorbed by the blue color resist, so that blue light is displayed. A relative positional relationship between the green color resist and the sub-pixel and a relative positional relationship between the red color resist and the sub-pixel may be determined with reference to the blue color resist, and will not be listed one by one in the embodiments of the present disclosure. A full color display may be achieved by mixing these three colors of monochromatic light according to actual needs.

The first planarization layer 240 covers above the color resist layer 230 and acts a planarization role, so that a subsequent film layer may be formed on a substantially flat surface, which is conducive to uniformity.

In the embodiments of the present disclosure, the light emitting functional layer 220 includes a plurality of light emitting devices 221, and the plurality of light emitting devices 221 include a first light emitting device 221A. The first light emitting device 221A may refer to a light emitting device 221 having a brightness-related viewing angle smaller than other light emitting devices 221 (such as the second light emitting device 221B) in the light emitting functional layer 220.

The first light emitting device 221A is one of the red sub-pixel, the green sub-pixel, or the blue sub-pixel. A specific light emission color of the first light emitting device 221A is not limited in the embodiments of the present disclosure. To meet practical needs, any of the brightness-related viewing angle of the light emitting device 221 of the red sub-pixel, the brightness-related viewing angle of the light emitting device 221 of the green sub-pixel, and the brightness-related viewing angle of the light emitting device 221 of the blue sub-pixel may be smaller than the other two. For example, the display substrate needs a blue light gain through the microcavity structure, and thus the light emitted by the light emitting device 221 of the blue sub-pixel may attenuate rapidly as the viewing angle increases. Therefore, the brightness-related viewing angle of the light emitting device 221 of the blue sub-pixel may be smaller than that of the red sub-pixel and that of the green sub-pixel. In another example, a red light gain is required through the microcavity structure, and thus the light emitted by the light emitting device 221 of the red sub-pixel may attenuate rapidly as the viewing angle increases. Therefore, the brightness-related viewing angle of the light emitting device 221 of the red sub-pixel may be smaller than that of the blue sub-pixel and that of the green sub-pixel.

In the embodiments of the present disclosure, it is expected to perform compensation for the light emitting device 221 that has a smaller brightness-related viewing angle. For clarity, unless otherwise specified, the first light emitting device 221 being the light emitting device 221 in the blue sub-pixel is illustrated by way of example in describing the display substrate of the embodiments of the present disclosure. Accordingly, other light emitting devices 221 in the light emitting functional layer 220 refer to the light emitting device 221 in the red sub-pixel and the light emitting device 221 in the green sub-pixel.

It will be noted that in addition to the above-mentioned microcavity structure, other factors such as a light emission area of the light emitting device 221 may also be a reason that the first light emitting device 221A has the minimum brightness-related viewing angle, which will not be listed one by one in the embodiments of the present disclosures.

The color resist layer 230 includes a plurality of color resists, and different color resists allow light of different colors to pass through. The plurality of color resists include a first color resist 2311.

In the embodiments of the present disclosure, the first color resist 2311 is the color resist located on the light exit side of the first light emitting device 221A. For example, if the first light emitting device 221A is the light emitting device 221 of the blue sub-pixel, then the first color resist 2311 is a blue color resist, that is, the first color resist 2311 only allows blue light to pass through. If the first light emitting device 221A is the light emitting device 221 of the red sub-pixel, then the first color resist 2311 is a red color resist, that is, the first color resist 2311 only allows red light to pass through.

FIG. 7 schematically shows a top view of a plurality of color resists according to the embodiments of the present disclosure. It will be noted that in the top view, the light emitting portion 2213 of the light emitting device is covered by the color resist. A positional relationship between the light emitting portion 2213 and the color resist is schematically shown in FIG. 7.

With reference to FIG. 6 and FIG. 7, the first color resist 2311 includes a first light transmitting portion H11. A surface of the first light transmitting portion H11 on a side close to the first planarization layer 240 includes a first curved surface recessed towards the base substrate 200. An orthographic projection of the first light emitting device 221A on the base substrate 200 falls within an orthographic projection of the first light transmitting portion H11 on the base substrate 200. The first color resist 2311 has a refractive index greater than the first planarization layer 240.

In the embodiments of the present disclosure, a plurality of other color resists adjacent to the first color resist 2311 in the color resist layer 230 may refer to color resists of other colors. For example, the first color resist 2311 is a blue color resist, and the plurality of other color resists adjacent to the blue color resist in the color resist layer 230 include a green color resist and a red color resist.

In the embodiments of the present disclosure, when preparing the color resist layer 230, the first color resist 2311 may be prepared last. Specifically, a color resist material used to form the first color resist 2311 (hereinafter also referred to as a material for the first color resist 2311) may be spin-coated on the base substrate 200. Optionally, a coating thickness of the first color resist 2311 material may be less than a coating thickness of other color resists, so that the material for the first color resist 2311 material may be simultaneously overlapped on adjacent color resists by using a centrifugal force during the spin-coating.

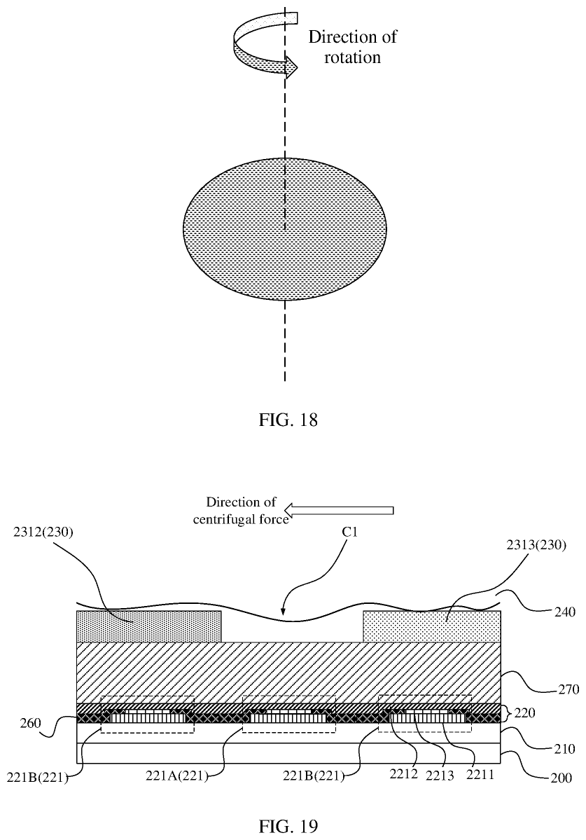

For example, FIG. 18 to FIG. 20 schematically show schematic diagrams of preparing a color resist layer by using spin-coating according to the embodiments of the present disclosure. Referring to FIG. 18 to FIG. 20, during the spin-coating, a first color resist material C1 between the second color resist 2312 (e.g., a red color resist) and the third color resist 2313 (e.g., a green color resist) flows to the left under the centrifugal force, so that the first color resist material C1 may be overlapped on the red color resist located on the left side. At the same time, under the centrifugal force, the first color resist material C1 on the green color resist also flows to the left and is overlapped on the green color resist located on the right side. Then the first color resist material C1 between the red color resist and the green color resist is recessed to form a concave surface. After exposure and development, a first color resist 2311 may be formed, and the first color resist material C1 between the red color resist and the green color resist may be formed as the first light transmitting portion H11 having the first curved surface.

FIG. 8 schematically shows a diagram of an optical path diagram from a light emitting device to a color resist according to the embodiments of the present disclosure.

Referring to FIG. 8, in the display substrate of the embodiments of the present disclosure, a lens structure may be formed using the first curved surface of the first color resist 2311 and the first planarization layer 240. Since the refractive index of the first color resist 2311 is greater than that of the first planarization layer 240, the lens structure is an optical concave lens having a divergence effect on incident light. Therefore, in the embodiments of the present disclosure, the concave lens may be used to perform compensation for a monochromatic light having a smaller brightness-related viewing angle among a plurality of monochromatic lights, so as to increase the brightness-related viewing angle of that monochromatic light.

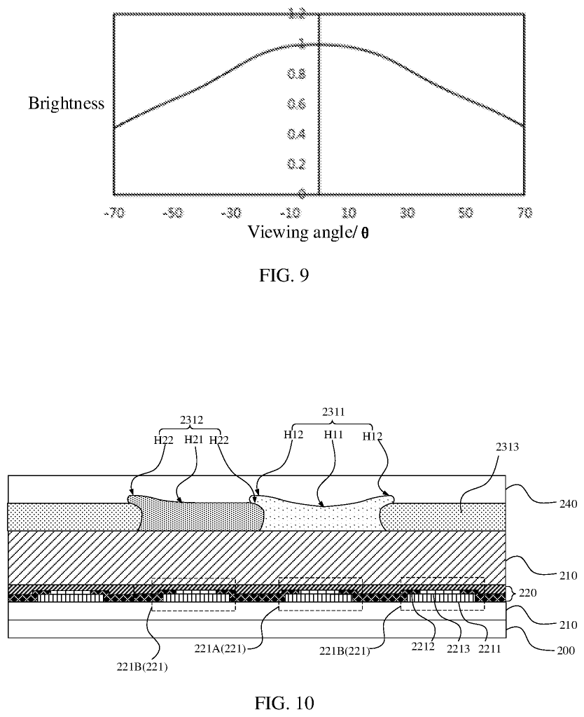

FIG. 9 schematically shows a brightness distribution diagram of blue light as a viewing angle varies according to the embodiments of the present disclosure.

Referring to FIG. 9, different from the solution in the comparative example, the solution in the embodiments of the present disclosure may increase the brightness-related viewing angle of the blue light through the first color resist, so as to improve the case of the small brightness-related viewing angle of a particular monochromatic light under a larger viewing angle (such as 50°) in a silicon-based micro display, so that the color shift under a large viewing angle may be mitigated, thereby increasing the color shift-related viewing angle and improving the display effect.

The display substrate of the embodiments of the present disclosure will be further described below.

In some specific embodiments, the first color resist 2311 includes a first edge portion H12 surrounding the first light transmitting portion H11. A surface of the first edge portion H12 on a side close to the first planarization layer 240 includes a second curved surface recessed towards the base substrate 200. A curvature radius of the first curved surface is greater than that of the second curved surface. In other words, for the surface of the first color resist 2311 away from the base substrate, the edge has a small curvature, while the middle has a large curvature, so that a divergence effect of the edge of the first color resist 2311 on light may be reduced, and therefore a light crosstalk between sub-pixels adjacent to each other may be avoided.

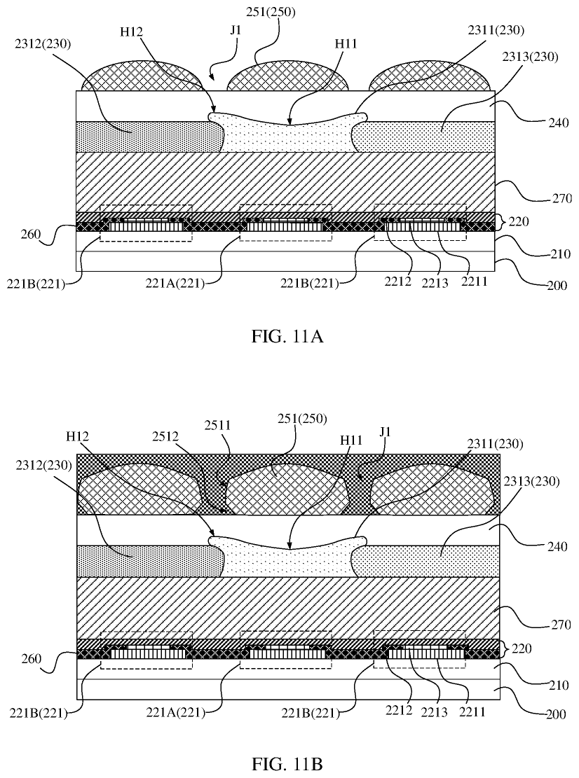

FIG. 10 schematically shows a schematic diagram of three color resists overlapping with each other according to the embodiments of the present disclosure.

Referring to FIG. 10, in some specific embodiments, the other color resists include the second color resist 2312 and the third color resist 2313.

In the embodiments of the present disclosure, the first color resist 2311 may be the blue color resist, and the second color resist 2312 and the third color resist 2313 may be color resists of other colors. For example, one of the second color resist 2312 and the third color resist 2313 is the red color resist, and the other of the second color resist 2312 and the third color resist 2313 is the green color resist.

In some specific embodiments, the first color resist 2311 overlaps with other color resists adjacent to it. In a region of an overlap between the first color resist 2311 and the color resists adjacent to the first color resist 2311, the first color resist 2311 is on a side of the other color resists away from the base substrate.

For example, the second color resist 2312 includes a second light transmitting portion H21 and a second edge portion H22 surrounding the second light transmitting portion H21. The first edge portion H12 overlaps with the second edge portion H22. The second edge portion H22 includes a first portion, and the first edge portion H12 is on a side of the first portion of the second edge portion H22 away from the base substrate 200. The third color resist 2313 is on a side of the second color resist 2312 away from the first color resist 2311. The second edge portion H22 includes a second portion, and the second portion is on a side of the third color resist 2313 away from the base substrate 200.

In some specific embodiments, in a direction from the first color resist 2311 to the second color resist 2312, an overlap between the first edge portion H12 and the first portion of the second edge portion H22 has a first overlapping size. In a direction from the second color resist 2312 to the third color resist 2313, an overlap between the second portion of the second edge portion H22 and the third color resist 2313 has a second overlapping size. The first overlapping size is greater than or equal to the second overlapping size.

In the embodiments of the present disclosure, when preparing the color resist layer 230, the third color resist 2313 may be prepared first. Specifically, a color resist material for forming the third color resist 2313 (hereinafter also referred to as a third color resist material) may be spin-coated on the base substrate 200. Afterwards, a third color resist 2313 may be formed by exposure and development, and a surface of the third color resist 2313 away from the base substrate 200 may be substantially flat. After the third color resist 2313 is prepared, the second color resist 2312 may be prepared. Specifically, a color resist material for forming the second color resist 2312 (hereinafter referred to as a second color resist material) is spin-coated on the base substrate 200. During the spin-coating, a coating thickness of the second color resist material is the same as that of the third color resist material. With a centrifugal force of the spin-coating, the second color resist material may be overlapped on the adjacent third color resist 2313, and an upper surface of the second color resist material may be substantially flat. Afterwards, the second color resist 2312 may be formed by exposure and development. A portion of the second color resist material that is overlapped on the third color resist 2313 forms the second portion of the second edge portion H22 in the second color resist 2312. The second light transmitting portion H21 and the first portion of the second edge portion H22 in the second color resist 2312 may be substantially flat.

In this way, overlapping the first color resist 2311, the second color resist 2312 and the third color resist 2313 with each other may contribute to a full coverage by the first color resist 2311, the second color resist 2312 and the third color resist 2313, so as to facilitate the prevention of light leakage. Moreover, in a region of the overlap between the adjacent color resists, superposition of two types of color resists may significantly reduce a transmittance in the region of the overlap, which may almost act like a black matrix to prevent a light crosstalk between sub-pixels.

The first edge portion H12 of the first color resist 2311 is overlapped on the first portion of the second edge portion H22 of the second color resist 2312 (i.e., a right edge of the second color resist 2312 in FIG. 10). In other words, the first portion of the second edge portion H22 of the second color resist 2312 is covered by the first edge portion H12 of the first color resist 2311. The overlapping portion has a first overlapping size, which may specifically refer to an average length of an overlap between the first color resist 2311 and the second color resist 2312 in the direction from the first color resist 2311 to the second color resist 2312.

The second portion of the second edge portion H22 of the second color resist 2312 (i.e., a left edge of the second color resist 2312 in the figure) is overlapped on an edge of the third color resist 2313 (i.e., a right edge of the third color resist 2313 in the figure). In other words, the second portion of the second edge portion H22 of the second color resist 2312 covers the edge of the third color resist 2313. The overlapping portion has a second overlapping size, which may specifically refer to an average length of an overlap between the second color resist 2312 and the third color resist 2313 in the direction from the second color resist 2312 to the third color resist 2313.

That is to say, in the embodiments of the present disclosure, the edge of the first color resist 2311 covers other color resists adjacent to it, and a portion of the edge of the second color resist 2312 covers the third color resist 2313. For any two color resists, an overlap between the two has an overlapping size, where the overlapping size of the first color resist 2311 and the second color resist 2312 is the first overlapping size, and the overlapping size of the second color resist 2312 and the third color resist 2313 is the second overlapping size. The first overlapping size being greater than the second overlapping size may contribute to better formation of the first curved surface of the first color resist 2311 in the spin-coating process, as well as formation of substantially flat upper surfaces when preparing the second color resist 2312 and the third color resist 2313. In this way, the monochromatic light passing through the first color resist 2311 may be diverged, and the brightness-related viewing angle may be therefore increased, while the monochromatic light passing through the second color resist 2312 and the third color resist 2313 may be hardly scattered, and the brightness-related viewing angle may remain almost unchanged, so that the plurality of monochromatic lights may have close brightness-related viewing angles.

In some specific embodiments, for other color resists that overlap with the first edge H12 of the first color resist 2311, the first overlapping sizes of the first color resist 2311 with any two of the other color resists may be substantially the same.

In the embodiments of the present disclosure, the first color resist 2311 overlaps with both the second color resist 2312 and the third color resist 2313. The first color resist 2311 may be in a shape of a rectangle, a pentagon, or a hexagon, etc. Therefore, the first color resist 2311 may be adjacent to more than one second color resist 2312 and more than one third color resist 2313, and thus overlaps with more than one second color resist 2312 and more than one third color resist 2313. Taking the first color resist 2311 being in a shape of a hexagon as an example, the first color resist 2311 is surrounded by three second color resists 2312 and three third color resists 2313. The first color resist 2311 overlaps with the six color resists with substantially the same overlapping size. Accordingly, from the center to any position on the edge, the first color resist 2311 may have substantially the same radian change trend, so that the curved surface of the first color resist 2311 may be a uniform curved surface, which may contribute to uniform divergence of light.

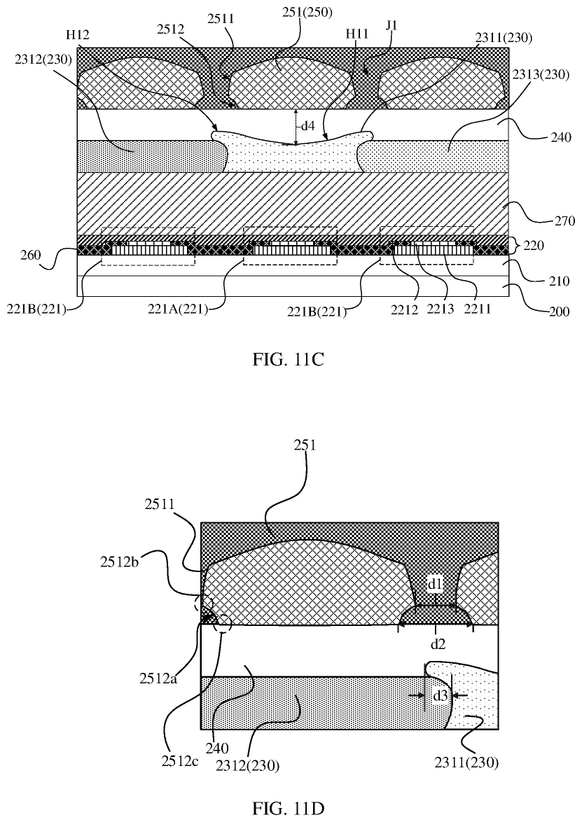

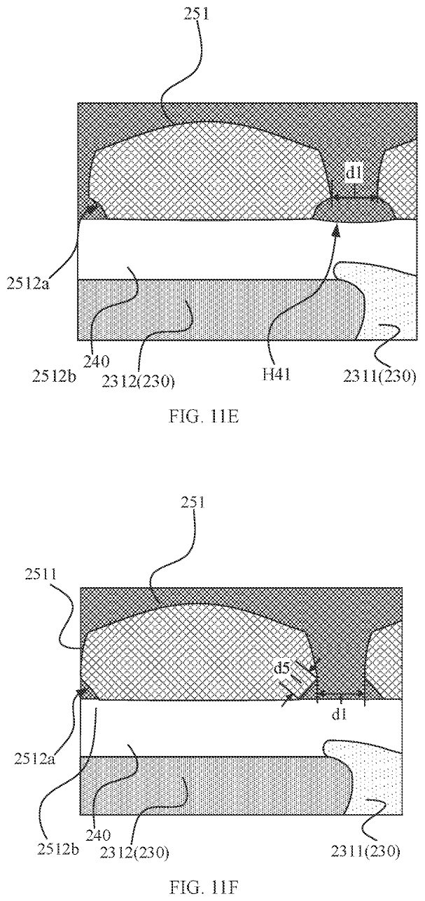

FIG. 11A to FIG. 11F schematically show schematic diagrams of providing a lens layer according to the embodiments of the present disclosure.

Referring to FIG. 11A to FIG. 11F, in some specific embodiments, the display substrate further includes a lens layer 250 provided on a side of the first planarization layer 240 away from the base substrate 200. The lens layer 250 includes a plurality of lenses 251, and a first gap J1 is formed between two lenses 251 adjacent to each other. An orthographic projection of the first gap J1 on the base substrate 200 at least partially overlaps with an orthographic projection of the overlap between color resists adjacent to each other on the base substrate 200 (such as an orthographic projection of the first edge portion H12 on the base substrate 200).

In the embodiments of the present disclosure, at least one lens 251 may be arranged directly opposite to at least one color resist, and the lens 251 may be used for convergence of the light emitted from the color resist, so as to improve a display brightness.

The lens 251 used in the silicon-based micro display has a very small size. To ensure a preparation accuracy, it is necessary to form the first gap J1 between lenses 251 adjacent to each other, so that each lens 251 may be accurately aligned with a color resist corresponding to it.

In the embodiments of the present disclosure, since a position of the overlap between the color resists has a small transmittance, the position of the overlap may be arranged to overlap with the first gap J1. That is, the orthographic projection of the first gap J1 on the base substrate 200 overlaps at least partially with the orthographic projection of the overlap between the color resists adjacent to each other on the base substrate 200, contributing to an improvement of a light utilization efficiency.

In some specific embodiments, the orthographic projection of the first gap J1 on the base substrate 200 covers the orthographic projection of the overlap between the color resists adjacent to each other on the base substrate 200. For example, for two lenses 251 adjacent to each other, the first color resist 2311 is provided on a light incidence side of one lens 251, and the second color resist 2312 is provided on a light incidence side of the other lens 251. An orthographic projection of an overlap between the first color resist 2311 and the second color resist 2312 (such as the first edge portion H12) on the base substrate 200 falls within an orthographic projection of the first gap J1 between the two lenses 251 on the base substrate 200.

In some specific embodiments, at least one first gap includes a groove 2512 recessed towards a center of the lens 251, in other words, a transverse groove 2512 is provided at a lower end of a side wall 2511 of the lens. The groove 2512 includes a first surface 2512a away from the base substrate 200. The first surface 2512a includes a flat surface or a smooth curved surface. For example, referring to FIG. 11B and FIG. 11F, the first surface 2512a is a flat surface. For another example, referring to FIG. 11C, the first surface 2512a may also be a smooth curved surface.

Optionally, the first surface 2512a of the groove 2512 is configured to reflect incident light that is incident into the groove 2512 in a predetermined direction.

In the embodiments of the present disclosure, the side wall 2511 of the lens 251 (such as a side of the side wall close to the first planarization layer 240) may be recessed at a bottom thereof in a horizontal direction, so as to form the groove 2512. The horizontal direction specifically refers to a direction perpendicular to a thickness direction of the display substrate. Optionally, the groove 2512 may be a ring structure surrounding the lens 251. The lens 251 corresponds to at least one sub-pixel, and the lens 251 is used for convergence of the light emitted from the corresponding sub-pixel, so as to enhance brightness. The predetermined direction may refer to a direction from an adjacent sub-pixel to the groove 2512 of the lens 251. The adjacent sub-pixel here specifically refers to a sub-pixel adjacent to the sub-pixel corresponding to the lens 251. The first surface 2512a of the groove 2512 on a side away from the base substrate 200 may be inclined, so that the first surface 2512a may reflect the incident light that is incident to the groove 2512 from the adjacent sub-pixel, thereby reducing light crosstalk between sub-pixels adjacent to each other.

Referring to FIG. 11D, in some specific embodiments, in the first gap J1, an edge 2512b of a first surfaces 2512a away from the base substrate 200 is spaced from an edge 2512b of another adjacent first surfaces 2512a away from the base substrate 200 by a first predetermined spacing d1, and an edge 2512c of the first surfaces 2512a close to the base substrate 200 is spaced from an edge 2512c of the adjacent first surfaces 2512a close to the base substrate 200 by a second predetermined spacing d2. The first predetermined spacing d1 is less than the second predetermined spacing d2. For example, the first predetermined spacing d1 may be set in a range of 0.5 μm to 0.6 μm, and the second predetermined spacing d2 may be set in a range of 0.8 μm to 1.0 μm.

In some specific embodiments, the first overlapping size d3 is less than the second predetermined spacing d2. For example, the first overlapping size may be set in a range of 0.2 μm to 0.6 μm.

Referring to FIG. 11C and FIG. 11D, in some specific embodiments, in the direction perpendicular to the base substrate 200, a spacing d4 between a center of the first curved surface and a surface of the first planarization layer 240 away from the base substrate 200 is greater than or equal to the first predetermined spacing d1. In other words, a distance between a lowest point of the first curved surface and an upper surface of the first planarization layer 240 is greater than the first predetermined spacing d1. Optionally, the spacing d4 between the center of the first curved surface and the surface of the first planarization layer 240 away from the base substrate 200 is less than the second predetermined spacing d2.

Referring to FIG. 11F, in some specific embodiments, in a direction from the edge 2512b of the first surface 2512a away from the base substrate 200 to the edge 2512c of the first surface close to the base substrate, the first curved surface has a first length d5, which is less than the first predetermined spacing d1.

Referring to FIG. 11B and FIG. 11F, cross sections of openings of grooves 2512 at two lenses 251 adjacent to each other face each other. The first predetermined spacing d1 may refer to, for a same first gap J1, a spacing between the edges 2512b of two first surfaces 2512a adjacent to each other in the horizontal direction. The second predetermined spacing d2 may refer to, for a same first gap J1, a spacing between the edges 2512c of two first surfaces 2512a adjacent to each other in the horizontal direction.

Optionally, a cross section of a portion of the first gap J1 above the groove 2512 may be substantially in a shape of an inverted trapezoid, in other words, a size of this portion gradually increases in a direction away from the base substrate 200. The first predetermined spacing d1 is less than or equal to a minimum size of that portion, and the second predetermined spacing d2 is greater than or equal to a maximum size of that portion.

In some specific embodiments, the second predetermined spacing d2 is less than a size of at least one lens 251 in the thickness direction of the display substrate.

In the embodiments of the present disclosure, the size of at least one lens 251 in the thickness direction of the display substrate, namely a height of the lens 251, may refer to a distance between a vertex of the lens 251 and a bottom surface of the lens 251. That is to say, in the embodiments of the present disclosure, for a same first gap J1, the spacing between the edges 2512c of two first surfaces 2512a adjacent to each other in the horizontal direction is less than the height of the lens 251.

In some specific embodiments, the first surface 2512a of at least one lens 251 has a first predetermined angle with the first planarization layer 240, and the first predetermined angle is an acute angle. Referring to FIG. 11B, a cross section of the groove 2512 substantially has a shape of a horizontally placed “V” shape.

Referring to FIG. 11C, in some other specific embodiments, the first surface 2512a may be a smooth curved surface, and the first predetermined angle may refer to an average angle between an end of the first surface 2512a close to a groove bottom 2512b and the first planarization layer 240.

In some specific embodiments, an orthographic projection of at least one lens 251 on the base substrate 200 falls within an orthographic projection of the first curved surface of the first color resist 2311 on the base substrate 200. In this way, the convergence of the light scattered by the first curved surface may be enabled through the lens 251 located above the first color resist 2311, so that the brightness-related viewing angle of the converging light may be increased. Optionally, an area of an overlap between the first light transmitting portion H11 of the first color resist 2311 and the lens 251 may be maximized. For example, the first light transmitting portion H11 of the first color resist 2311 may be arranged directly facing the lens 251.

In some specific embodiments, a depth of the first curved surface is less than or equal to a size of at least one lens 251 in the thickness direction of the display substrate, so that a degree of curvature of the first curved surface is not too large. The depth of the first curved surface may specifically refer to a size of the first curved surface between upper and lower limits of the first curved surface in the thickness direction of the display substrate.

In some specific embodiments, the distance d4 between the center of the first curved surface and the surface of the first planarization layer 240 away from the base substrate 200 in the direction perpendicular to the base substrate 200 is less than or equal to a maximum height of at least one lens 251. The maximum height of the lens 251 may refer to a distance between the vertex of the lens 251 and the bottom surface (or lowest point) of the lens 251 in the direction perpendicular to the base substrate 200. Thus, a degree of divergence of light caused by the concave lens formed by the first curved surface match the lens 251 well.

Referring to FIG. 11E, in some specific embodiments, the first gap J1 includes a third surface H41 on a side close to the base substrate, and the third surface H41 has a curvature radius smaller than the first curved surface. For lenses 251 adjacent to each other, in the thickness direction of the display substrate, an edge of the third curved surface H41 overlaps with the first surfaces 2512a of the two lenses 251, and a middle of the third curved surface H41 overlaps with the first gap J1 between the two lenses 251. The third curved surface H41 may be a curved surface recessed towards the base substrate 200, and this is because during the formation of the lens layer 250, it is necessary to perform over etching, so as to ensure that the plurality of lenses 251 are spaced apart from each other, and the grooves 2512 may be formed at the bottoms of the side walls 2511 of the lenses 251.

In some specific embodiments, a ratio of the light emission area of the first light emitting device 221A to an area of the orthographic projection of the first curved surface on the base substrate 200 is greater than or equal to 1:2.

In the embodiments of the present disclosure, the light emission area of the first light emitting device 221A may refer to an area of a portion of the light emitting portion 2213 of the first light emitting device 221A located in a pixel opening of a pixel defining layer 260.

For example, the pixel defining layer 260 is provided between the light emitting portion 2213 and the first electrodes 2211. Pixel openings are provided in the pixel defining layer 260 and expose the first electrodes 2211. The light emitting portion 2213 includes a portion located in the pixel opening and a portion located outside the pixel opening. For the light emitting portion 2213, the portion located in the pixel opening is electrically connected to a first electrode 2211, and the portion located outside the pixel opening is separated from the first electrode 2211 by the pixel defining layer. Therefore, the portion of the light emitting portion 2213 located in the pixel opening may emit light in response to an electrical signal applied to the first electrode 2211. The area of the portion of the light emitting portion 2213 located in the pixel opening is an effective light emission area of the light emitting device 221.

For example, the ratio of the light emission area of the first light emitting device 221A to the area of the orthographic projection of the first curved surface on the base substrate 200 may be set to 1:1.5. In this way, the curvature radius of the first curved surface may match the distance from the first curved surface to the first light emitting device 221A, thereby achieving a good light divergence effect.

In some specific embodiments, an average thickness of either the second color resist 2312 or the third color resist 2313 is greater than an average thickness of the first color resist 2311

In the embodiments of the present disclosure, the average thickness of the second color resist 2312 is substantially the same as the average thickness of the third color resist 2313. For example, a surface of the third color resist 2313 close to the base substrate 200 and a surface of the third color resist 2313 away from the base substrate 200 are substantially flat. Therefore, the third color resist 2313 has substantially the same thickness at all positions. A surface of the second light transmitting portion H21 of the second color resist 2312 close to the base substrate 200 and a surface of the second light transmitting portion H21 of the second color resist 2312 away from the base substrate 200 are substantially flat. Therefore, the second light transmitting portion H21 has substantially the same thickness at all positions. Optionally, the thickness of the second light transmitting portion H21 of the second color resist 2312 is substantially the same as the thickness of the third color resist 2313.

In the embodiments of the present disclosure, a difference between the average thickness of either the second color resist 2312 or the third color resist 2313 and the average thickness of the first color resist 2311 is a first predetermined difference. A ratio of the first predetermined difference to the average thickness of either the second color resist 2312 or the third color resist 2313 is less than or equal to 1:5. For example, the ratio of the first predetermined difference to the average thickness of either the second color resist 2312 or the third color resist 2313 is less than 1:5. With such size design, it is easy to form the first curved surface on the first color resist 2311 using a stress caused by spin-coating in the spin-coating process, while ensuring that the thickness of the first color resist 2311 meets normal filtering requirements.

In some specific embodiments, the display substrate further includes an encapsulation layer 270 between the light emitting functional layer 220 and the color resist layer 230.

In the embodiments of the present disclosure, the encapsulation layer 270 may be a composite film layer composed of a plurality of film layers. For example, the encapsulation layer 270 may include a first organic encapsulation layer 270, a first inorganic encapsulation layer 270 and a second organic encapsulation layer 270 sequentially arranged in the direction away from the base substrate 200, so that the flexibility and the encapsulation effect may be good. Alternatively, each film layer in the encapsulation layer 270 is made of an inorganic material, which may be determined according to actual needs and will not be listed in the embodiments of the present disclosure.

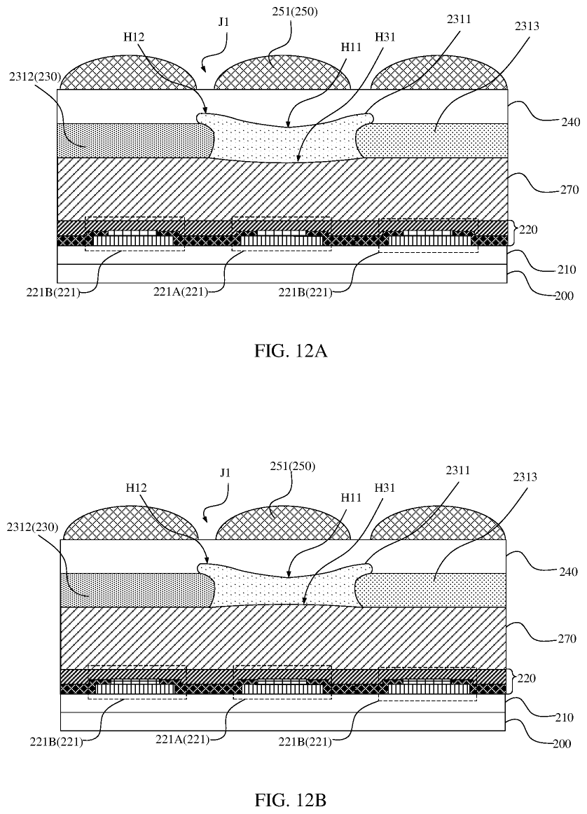

FIG. 12A and FIG. 12B schematically show schematic diagrams of a fourth curved surface of an encapsulation layer according to the embodiments of the present disclosure.

Referring to FIG. 12A and FIG. 12B, in the embodiments of the present disclosure, the encapsulation layer 270 includes at least one fourth curved surface H31 on a side close to the color resist layer 230. An orthographic projection of the at least one fourth curved surface H31 on the base substrate 200 overlaps at least partially with the orthographic projection of the first color resist layer 2311 on the base substrate 200.

In the embodiments of the present disclosure, the light emitting device 221 includes the first electrode 2211 and the second electrode 2212, one of the first electrode 2211 and the second electrode 2212 is an anode, and the other is a cathode. For example, the first electrode 2211 is on a side of the second electrode 2212 close to the base substrate 200, the first electrode 2211 is an anode, and the second electrode 2212 is a cathode.

Nowadays, when preparing the anode, due to limitations of the preparation process, the anode may have a significant step difference. Specifically, in an embodiment, a process of preparing the anode and the cathode includes: depositing a layer of conductive film on the base substrate 200 and applying a layer of photoresist on the conductive film; forming a photoresist pattern by exposure and development; and then forming an anode pattern by etching the conductive film not covered by the photoresist using a dry etching process. The etching process may cause a loss etch in the film layer below the conductive film in an etching region, and a depth h of the loss etch is generally about 200 angstroms to 300 angstroms. Due to the depth h in combination of the thickness of the transparent conductive film, the step difference between the anode 400 and the film layer below the anode may reach about 900 angstroms to 1000 angstroms.

After the formation of the encapsulation layer 270, due to the large step difference of the anode, a small step difference may still appear on a surface of the encapsulation layer 270 away from the base substrate 200, and the small step difference specifically manifested as a small protrusion or small recess on the surface of the encapsulation layer 270 away from the base substrate 200.

In the embodiments of the present disclosure, the small protrusion or small recess may be used to further increase the brightness-related viewing angle. Specifically, in the embodiments of the present disclosure, the fourth curved surface H31 and the encapsulation layer 270 are configured such that, for incident light incident into the first color resist 2311 through the fourth curved surface H31, a brightness-related viewing angle after the incident light is incident to the first color resist 2311 is greater than or equal to a brightness-related viewing angle before the incident light is incident to the first color resist 2311. For example, in the embodiments of the present disclosure, it is possible to adjust the refractive indexes of the first color resist 2311 and the encapsulation layer 270, so that the refractive indexes of the two match the small protrusion or small recess on the encapsulation layer 270, thereby forming a lens 251 having a divergence function.

For example, referring to FIG. 12A, for the fourth curved surface H31 and the first color resist 2311 located on the fourth curved surface H31, the fourth curved surface H31 includes a curved surface recessed towards the base substrate 200, and the refractive index of the first color resist 2311 is less than that of the encapsulation layer 270. In this way, the fourth curved surface H31 and the first color resist 2311 may form a lens 251 structure, and since the refractive index of the first color resist 2311 is less than that of the encapsulation layer 270, the lens 251 structure is an optical concave lens 251 that may diffuse light incident from the upper side, so that the brightness-related viewing angle may be increased.

For another example, referring to FIG. 12B, the fourth curved surface H31 includes a curved surface protruding towards the first planarization layer 240, and the refractive index of the first color resist 2311 is greater than that of the encapsulation layer 270. In this way, the fourth curved surface H31 and the first color resist 2311 may form a lens 251 structure, and since the refractive index of the first color resist 2311 is greater than that of the encapsulation layer 270, the lens 251 structure is still an optical concave lens 251 that may also diffuse light incident from the upper side, so that the brightness-related viewing angle may be increased.

In some specific embodiments, at least one light emitting device 221 includes the first electrode 2211, the second electrode 2212, and the light emitting portion 2213 between the first electrode 2211 and the second electrode 2212.

In some specific embodiments, the light emitting portion 2213 includes a first light emitting sub-portion and a second light emitting sub-portion (not shown) stacked in the thickness direction of the display substrate. Optionally, the first light emitting sub-portion is a yellow light emitting portion 2213. For example, the first light emitting sub-portion is composed of a red light emitting portion 2213 and a green light emitting portion 2213; and the second light emitting sub-portion is a blue light emitting portion 2213. According to the principle of complementarity of light, blue light and yellow light mix to form white light.

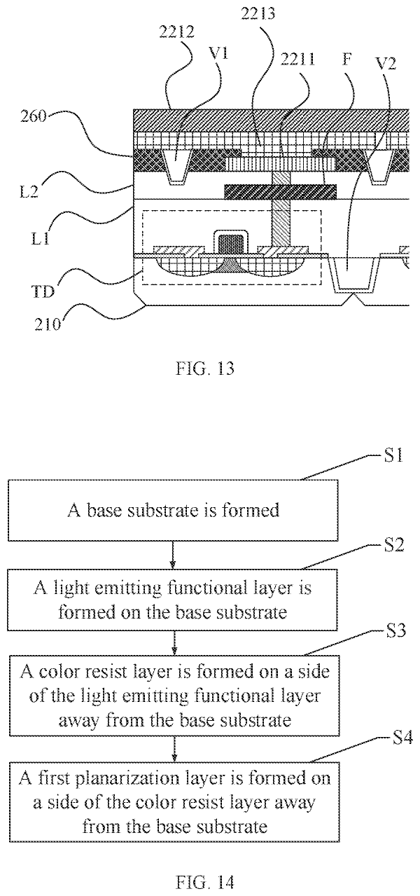

FIG. 13 schematically shows a schematic diagram of forming a microcavity structure according to the embodiments of the present disclosure.

Referring to FIG. 13, the first electrode 2211 and the second electrode 2212 form a microcavity structure, which is used to produce a gain to light having a first color. The light allowed to pass through the first color resist 2311 includes the light of the first color.

In the embodiments of the present disclosure, the first electrode 2211 may include a reflective material capable of reflecting light. Due to a strong reflection effect of the first electrode 2211, the light directly emitted by the light emitting portion 2213 interferes with the light reflected by the first electrode 2211, so that not only a color gamut of the emitted light may be improved, but also the brightness of the emitted light may be enhanced, thereby achieving the gain of light. For the microcavity effect, it is required to meet δ=2j(λ/2)=2nd cos θ, where δ represents a phase difference of the microcavity, j is an integer, λ represents a wavelength of the exit light, n represents an average refractive index of a medium in the microcavity, d represents a microcavity length, and θ represents a reflection angle. From the above formula for an optical path difference of the microcavity, the microcavity length d is positively proportional to the wavelength λ of the exit light, and the microcavity length increases as the wavelength of the exit light increases. As the wavelength of light corresponds to the color of light, it is possible to obtain microcavity lengths required for light of different colors to undergo strong microcavity effects. In a specific implementation, the microcavity length may be set according to actual needs and is not limited here.

Optionally, in some other embodiments, the first electrode 2211 may be made of a transparent material. A reflective electrode F electrically connected to the first electrode 2211 may be provided on a side of the first electrode 2211 close to the base substrate 200, and the reflective electrode F includes a reflective material. The reflective electrode F is used to form a microcavity structure with the second electrode 2212, so that the microcavity length may be increased.

Optionally, the first electrode 2211 may be electrically connected to a first electrode of a driving transistor in the pixel circuit through the reflective electrode F.

In some specific embodiments, in addition to the driving transistor, the pixel circuit may include an input transistor, a reset transistor, a light emission control transistor, and a storage capacitor. The input transistor, the reset transistor and the light emission control transistors may all be metal oxide semiconductor (MOS) field-effect transistors prepared in a silicon-based substrate.

Optionally, the pixel driver circuit may have a circuit structure of 3T1C, 5T1C, 7T1C, or the like, or a circuit structure having an internal or external compensation function, which is not limited in the present disclosure.

In some specific embodiments, the display substrate may further include a cover plate, which is provided on a side of the color resist layer 230 away from the base substrate 200, so as to achieve a protection function for the color resist layer 230.

In an example, the cover plate is connected to the base substrate 200 through a sealant. The sealant is provided between the base substrate 200 and the cover plate, and the sealant may provide a further protection against water and oxygen intrusion, so that a service life of the display substrate may be greatly improved.

In another example, the sealant may be provided on side surfaces of the cover plate, and four side surfaces of the cover plate are sealed with the base substrate 200 through the sealant. An end surface of the sealant on a side away from the base substrate 200 is located between a surface of the cover plate close to the base substrate 200 and a surface of the cover plate away from the base substrate 200. In this way, a sealing effect may be ensured, while preventing the sealant from exceeding the cover plate and causing an increase in the thickness of the display substrate.

It will be understood that an insulation layer located between the conductive film layers may be further provided in the display substrate. For example, an insulation layer L1 is provided between the driving transistor TD and the reflective electrode, and an insulation layer L2 is provided between the reflective electrode and the first electrode, which will not be listed in the embodiments of the present disclosure.

In some specific embodiments, the insulation layer L2 may be provided with a groove V1, which is used to form a misalignment for the light emitting portion 2313 at the groove V1, so that the light emitting portions 2313 of two sub-pixels adjacent to each other may be separated at the groove V1.

In some specific embodiments, a groove V2 may be provided on the base substrate, which is used to form a misalignment for components in pixel circuits adjacent to each other at the groove V2, so that the pixel circuits of two sub-pixels adjacent to each other may be separated at the groove V2.

In some specific embodiments, the first planarization layer 240 may be made of SiC or SiCNx. Because SiC or SiCNx tends to have inorganic properties, on the one hand, it may protect the color resist layer 230 to reduce aging damage to the color resist layer 230 and increase service life. On the other hand, a flat surface may be formed to facilitate leveling of an adhesive material in a subsequent process of bonding the cover plate, so as to improve the bonding quality of the cover plate.

In some specific embodiments, other light emitting devices 221 in the light emitting functional layer 220 include second light emitting devices 2212.

In the embodiments of the present disclosure, the second light emitting device 221B may refer to a light emitting device 221 that belongs to a sub-pixel being not the sub-pixel including the first light emitting device 221A. For example, if the first light emitting device 221A belongs to a blue sub-pixel, then the second light emitting device 221B may refer to the light emitting device 221 in a red sub-pixel and the light emitting device 221 in a green sub-pixel.

In the embodiments of the present disclosure, the light emission area of the first light emitting device 221A is substantially the same as that of the second light emitting device 221B. The light emission area of the second light emitting device 221B specifically refers to an effective light emission area of the second light emitting device 221B. The effective light emission area has been explained in detail in the aforementioned embodiments, which will not be repeated here.

An orthographic projection of the second light emitting device 221B on the base substrate 200 falls within the orthographic projection of the second light transmitting portion H21 of the second color resist 2312 on the base substrate 200. For example, the light emitting device 221 of the red sub-pixel is below the red color resist, and the light emitting device 221 of the green sub-pixel is below the green color resist.

An area of the orthographic projection of the first light transmitting portion H11 of the first color resist 2311 (which is also a portion of the first color resist mainly used for light transmission) on the base substrate 200 is substantially the same as an area of the orthographic projection of the second light transmitting portion H21 of the second color resist 2312 (which is also a portion of the second color resist mainly used for light transmission) on the base substrate 200. That is to say, for the first color resist and the second color resist 2312, after removing, remaining portions other than the overlap between the two color resists have substantially the same area.

Accordingly, the third color resist 2313 includes a third light transmitting portion, and a third edge portion that is covered by the first color resist and the second color resist 2312. The third edge portion is arranged around the third light transmitting portion. Orthographic projections of the first light transmitting portion H11, the second light transmitting portion H21 and the third light transmitting portion on the base substrate 200 are substantially the same.

It will be noted that the area of the color resist mentioned above needs to be set according to the light emission area of the light emitting device 221 below the color resist. For example, when the first light emitting device 221A and the second light emitting device 221B have the same light emission area, the first color resist and the second color resist 2312 may have the same area. However, when the light emission area of either the first light emitting device 221A or the second light emitting device 221B is increased, the area of the corresponding color resist may be increased accordingly, then the area of the first color resist and the area of the second color resist 2312 are different.

In some specific embodiments, for the first color resist 2311, an orthographic projection of the at least one fourth curved surface H31 on the base substrate 200 falls within the orthographic projection of the first curved surface on the base substrate 200.

In the embodiments of the present disclosure, the fourth curved surface H31 is caused by the step difference of the anode, and therefore has a smaller radian compared to the first curved surface. For example, the first curved surface may cover one or more fourth curved surfaces H31. The radian of the first curved surface (or the fourth curved surface H31) may refer to an average radian of the first curved surface (or the fourth curved surface H31).

In some specific embodiments, for the first color resist 2311, in a direction from the center of the first color resist 2311 to the edge of the first color resist 2311, a ratio of a size of the first edge portion H12 to a size of the first light transmitting portion H11 is greater than or equal to 1:10. Thus, the first curved surface may have a good degree of concave and thus have a good curvature radius, so that the light divergence effect may be good.

The first edge region H12 overlaps with the second color resist 2312 and the third color resist 2313. Due to the small transmittance of the overlapping portion, this portion may almost act like a black matrix to prevent a light crosstalk between sub-pixels adjacent to each other.

In some specific embodiments, the first curved surface and the first planarization layer 240 are configured such that a brightness-related viewing angle of first light emitted from the first planarization layer 240 is substantially the same as a brightness-related viewing angle of either second light or third light emitted from the first planarization layer 240. The color of the first light includes the color of light allowed to pass through the first color resist 2311, the color of the second light includes the color of light allowed to pass through the second color resist 2312, and the color of the third light includes the color of light allowed to pass through the third color resist 2313.

For example, the first light is blue light, the second light is red light, and the third light is green light. Any one of the red, green and blue monochromatic lights emitted from the color resist layer 230 has a brightness-related viewing angle substantially the same as the brightness-related viewing angle of the other monochromatic lights, so that the monochromatic lights of these three colors have consistent brightness reduction tends as the viewing angle increases, so that the problem of color shift may be prevented in a large range of viewing angle.

In some specific embodiments, for the first lens 251, the first curved surface of the first color resist 2311 and the light emitting portion 2213 of the first light emitting device 221A, these three are arranged coaxially, so that optical axes of these three may coincide.

In the embodiments of the present disclosure, the orthographic projection of the portion of the light emitting portion 2213 of the first light emitting device 221A located in the pixel opening on the base substrate 200 has the same shape as the orthographic projection of the first color resistor 2311 on the base substrate 200. For example, the orthographic projection of the portion of the light emitting portion 2213 of the first light emitting device 221A located in the pixel opening on the base substrate 200 is in a shape of a hexagon (in other words, a pattern of the pixel opening is in a shape of a hexagon), then the orthographic projection of the first color resistor 2311 on the base substrate 200 may also be in a shape of a hexagon, and the two are coaxial and face to each other.

The embodiments of the present disclosure further provide a method of manufacturing a display substrate. A manufacturing process according to the embodiments will be explained below with reference to FIG. 14 to FIG. 19.

It will be noted that the “patterning process” mentioned in the present disclosure includes deposition of a film layer, coating of a photoresist, mask exposure, development, etching, stripping of the photoresist. Deposition may be performed using any one or more of sputtering, evaporation and chemical vapor deposition, coating may be performed using any one or more of spraying and spin-coating, and etching may be performed using any one or more of dry etching and wet etching. “Film” refers to a layer of thin film made of a certain material on a base substrate by a deposition or coating process. If the “film” does not require a patterning process during the entire manufacturing process, the “film” may also be referred to as a “layer”. If the “film” needs a patterning process in the manufacturing process, it is referred to as a “film” prior to the patterning process and as a “layer” subsequent to the patterning process. The “layer” subsequent to the patterning process includes at least one “pattern”. In the present disclosure, “A and B are arranged in the same layer” means that A and B are simultaneously formed through the same patterning process. In the present disclosure, “an orthographic projection of A includes an orthographic projection of B” means that the orthographic projection of B falls within a range of the orthographic projection of A, or the orthographic projection of A covers the orthographic projection of B.

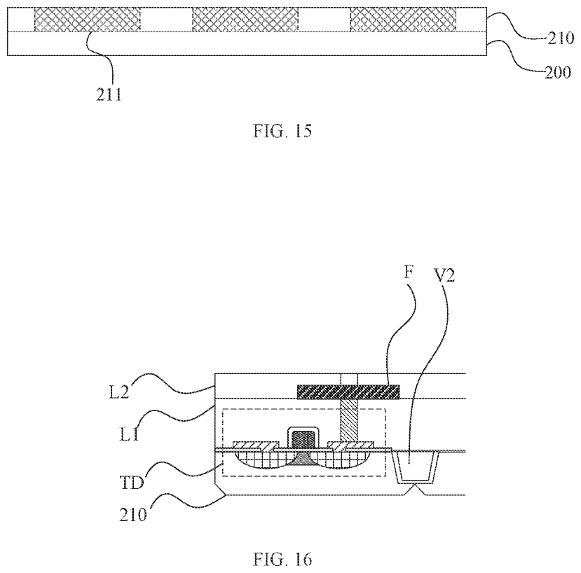

FIG. 14 schematically shows a flowchart of forming a display substrate according to the embodiments of the present disclosure. FIG. 15 to FIG. 22 schematically show schematic diagrams of stages of a manufacturing process of a display substrate according to the embodiments of the present disclosure, where FIG. 18 shows a schematic diagram of a spin-coating direction in a spin-coating process.

Referring to FIG. 14 to FIG. 22, the method of manufacturing the display substrate in the embodiments of the present disclosure includes step S1 to step S4.

In step S1, a base substrate 200 is formed.

In the embodiments of the present disclosure, the base substrate 200 may specifically refer to a silicon-based substrate, and a process of forming the silicon-based substrate may be a mature IC wafer process in the related art, which will not be described in detail here.

A driver circuit layer 210 is formed on the base substrate 200. The driver circuit layer 210 may include a plurality of pixel circuits 211, and each pixel circuit includes a plurality of transistors including a driving transistor TD. As for the driving transistor TD, reference may be made to that shown in FIG. 16.

A first insulation layer L1 is formed, specifically including: depositing an insulation film on the substrate formed with the aforementioned pattern, and patterning the insulation film by using a patterning process to form a first insulation layer covering the driving transistor TD. A via hole is formed in the first insulation layer to expose a drain electrode of the driving transistor TD.

A reflective electrode F is formed, specifically including: depositing a reflective metal film on the substrate formed with the aforementioned pattern, and patterning the reflective metal film by using a patterning process to form a pattern of the reflective electrode F. The reflective electrode F is electrically connected to the drain electrode of the driving transistor through the via hole in the first insulation layer. The reflective metal film may be made of a metal material such as silver Ag, copper Cu, aluminum Al, and molybdenum Mo, or an alloy material of the aforementioned metal(s). Optionally, the reflective metal film is made of aluminum Al.

A second insulation layer L2 is formed, specifically including: depositing an insulation film on the substrate formed with the aforementioned pattern, and patterning the insulation film by using a patterning process to form a second insulation layer covering the reflective electrode F. A via hole is formed in the second insulation layer to expose the reflective electrode F.

In step S2, a light emitting functional layer 220 is formed on the base substrate 200. The light emitting functional layer 220 includes at least one light emitting device 221. A plurality of light emitting devices 221 include a first light emitting device 221A, which has a brightness-related viewing angle smaller than that of other light emitting devices 221 in the light emitting functional layer 220.

In the embodiments of the present disclosure, the light emitting device 221 includes a first electrode 2211, a second electrode 2212, and a light emitting portion 2213 between the first electrode 2211 and the second electrode 2212. Processes of forming the first electrode 2211, the second electrode 2212 and the light emitting portion 2213 will be explained below, respectively.

The formation of the first electrode 2211 specifically includes: depositing a layer of transparent conductive film on the base substrate formed with the aforementioned pattern, applying a layer of photoresist on the transparent conductive film, forming a photoresist pattern by masking, exposure and development, then etching the transparent conductive film not covered by the photoresist using a dry etching process to form the first electrode 2211, and finally stripping the remaining photoresist to complete the preparation of the first electrode 2211.

The formation of the light emitting layer and the second electrode 2212 specifically includes: applying a pixel defining film on the substrate formed with the aforementioned pattern, forming a pixel defining layer using masking, exposure and development, where a plurality of pixel openings are provided in the pixel defining layer, the pixel opening exposing the first electrode 2211, then forming a light emitting portion 2213 in each pixel opening, and finally depositing a transflective metal film on the substrate formed with the aforementioned pattern to form the second electrode 2212.

In the embodiments of the present disclosure, the reflective electrode F and the second electrode 2212 form a microcavity structure. Due to a strong reflection effect of the reflective electrode F, the light directly emitted by the subsequently formed light emitting portion 2213 interferes with the light reflected by the reflective electrode F, so that not only a color gamut of the emitted light may be improved, but also the brightness of the emitted light may be enhanced, thereby achieving the gain of the emitted light.

The light emitting portion 2213 in the embodiments of the present disclosure includes a first light emitting sub-portion, a first charge generating portion, a second light emitting sub-portion, a second charge generating portion and a third light emitting sub-portion that are stacked sequentially between the first electrode 2211 and the second electrode 2212. The first light emitting sub-portion includes a first hole transport layer, a first light-emitting material layer and a first electron transport layer stacked sequentially. The second light emitting sub-portion includes a second hole transport layer, a second light-emitting material layer and a second electron transport layer stacked sequentially. The third light emitting sub-portion includes a third hole transport layer, a third light-emitting material layer and a third electron transport layer stacked sequentially. The first charge generating portion is provided between the first light-emitting sub-portion and the second light-emitting sub-portion, and is used to connect the two light-emitting sub-portions in series to achieve transmission of charge carriers. The second charge generating portion is provided between the second light-emitting sub-portion and the third light-emitting sub-portion, and is used to connect the two light-emitting sub-portions in series to achieve transmission of charge carriers. The first light-emitting material layer, the second light-emitting material layer and the third light-emitting material layer are used to emit light of different colors, so that the final emitted light from the light emitting portion 2213 is mixed light. For example, the first light-emitting material layer may be set as a red light material layer that emits red light, the second light-emitting material layer may be set as a green light material layer that emits green light, and the third light-emitting material layer may be set as a blue light material layer that emits blue light. Therefore, the light emitted by the emitting layers is emits white light, ultimately.

In step S3, a color resist layer 230 is formed on a side of the light emitting functional layer 220 away from the base substrate 200. The color resist layer 230 includes a plurality of color resists, and different color resists allow light of different colors to pass through. The plurality of color resists include a first color resist 2311. A surface of the first color resist 2311 on a side away from the base substrate 200 includes a first curved surface recessed towards the base substrate 200. The first curved surface includes a first light transmitting portion H11, and a first edge portion H12 surrounding the first light transmitting portion H11. An orthographic projection of the first light emitting device 221A on the base substrate 200 falls within an orthographic projection of the first light transmitting portion H11 on the base substrate 200. For the first color resist 2311 and a plurality of other color resists adjacent to the first color resist 2311 in the color resist layer 230, the first edge portion H12 is overlapped on the sides of the plurality of other color resists away from the base substrate 200.

The formation of the color resist layer 230 specifically includes: forming a encapsulation layer 270 that encapsulates the aforementioned film layers, by depositing an inorganic material and/or applying an organic material on the substrate formed with the aforementioned pattern; and then forming a color resist layer 230 on the encapsulation layer 270 by applying a color resin film, masking, exposure, and development. The color resist layer 230 includes a first color resist 2311, a second color resist 2312 and a third color resist 2313, which are used to allow different monochromatic lights to pass through.

In the embodiments of the present disclosure, when preparing the color resist layer 230, the first color resist 2311 may be prepared last. Specifically, a color resist material used to form the first color resist 2311 (hereinafter also referred to as a first color resist material C1) may be spin-coated on the base substrate 200. Optionally, a coating thickness of the first color resist material C1 may be less than a coating thickness of other color resists, so that the first color resist material C1 may be simultaneously overlapped on an adjacent red color resist and an adjacent green color resist using a centrifugal force during the spin-coating.

For example, during the spin-coating, the first color resist material C1 between the red color resist and the green color resist flows to the left under the centrifugal force, so that the first color resist material C1 may be overlapped on the red color resist located on the left side. At the same time, the first color resist material C1 on the green color resist also flows to the left and is overlapped on the green color resist located on the right side. Then the first color resist material C1 between the red color resist and the green color resist is recessed to form a concave surface. After exposure and development, a first color resist 2311 may be formed, and the first color resist material C1 between the red color resist and the green color resist may be formed as the first light transmitting portion H11 having the first curved surface.

Optionally, when forming the color resist layer 230, a corresponding black matrix and other structures may also be formed.

In step S4, a first planarization layer 240 is formed on a side of the color resist layer 230 away from the base substrate 200. A refractive index of the first color resist layer 2311 is greater than that of the first planarization layer 240.

Using the manufacturing method of the embodiments of the present disclosure, a structure of a lens 251 may be formed using the first curved surface of the first color resist 2311 and the first planarization layer 240. Since the refractive index of the first color resist is greater than that of the first planarization layer 240, the structure of the lens 251 is an optical concave lens having a divergence effect on incident light. Therefore, in the embodiments of the present disclosure, the concave lens 251 may be used to perform compensation for a monochromatic light having a smaller brightness-related viewing angle among a plurality of monochromatic lights, so as to increase the brightness-related viewing angle of that monochromatic light. Compared to the solution in the comparative example, the solution in the embodiments of the present disclosure may improve a small brightness-related viewing angle of a monochromatic light in the silicon-based micro display, so that the small color shift-related viewing angle may be increased and the display effect may be improved.

In some specific embodiments, the other color resists in the color resist layer 230 include the second color resist 2312 and the third color resist 2313, and the formation of the color resist layer 230 on the side of the light emitting functional layer 220 away from the base substrate 200 includes the following steps.

The second color resist 2312 and the third color resist 2313 are formed on a side of the light emitting functional layer 220 away from the base substrate 200 by using a spin-coating process, where the second color resist 2312 and the third color resist 2313 adopt a first coating thickness.

A first color resist material C1 is formed on a side of the light emitting functional layer 220 away from the base substrate 200.

The first color resist material C1 is spin-coated to a second coating thickness. The second coating thickness is less than the first coating thickness and is specifically configured such that in the spin-coating process, the first color resist material C1 between the second color resist 2312 and the third color resist 2313 may form a first recess, and an edge of the first recess may be overlapped on the side of the second color resist 2312 away from the base substrate 200 and the side of the third color resist 2313 away from the base substrate 200.

The first recess is retained by exposure and development, so as to obtain the first color resist 2311 having a first curved surface. Specifically, an opening size of a mask used to form the first color resist 2311 may be adjusted appropriately, so that a portion of the first color resist 2311 overlapped on the other color resists may be retained after the exposure and development, thereby forming the first curved surface.

In this way, the preparation of the first color resist 2311 having the first curved surface may be achieved by only adjusting the coating thickness and the opening size of the mask plate used to form the first color resist 2311 on the basis of the original spin-coating process, and the existing process does not have to be changed significantly, so that the existing process may not be affected, and the costs for improvement may be relatively low.

In other specific embodiments, the other color resists in the color resist layer 230 include the second color resist 2312 and the third color resist 2313, and the formation of the color resist layer 230 on the side of the light emitting functional layer 220 away from the base substrate 200 includes the following steps.

The second color resist 2312 and the third color resist 2313 are formed on a side of the light emitting functional layer 220 away from the base substrate 200 by using a spin-coating process, where the second color resist 2312 and the third color resist 2313 adopt a first coating thickness.

A first color resist material C1 is formed on the side of the light emitting functional layer 220 away from the base substrate 200.

The first color resist material C1 is spin-coated to a third coating thickness greater than the first coating thickness.

Exposure and development are performed on the first color resist material C1 by using a semi-transparent mask process. A semi-transparent mask plate has a gradient transmittance, and is specifically configured such that: during the exposure and development, the first color resist material C1 between the second color resist 2312 and the third color resist 2313 may form a first recess, and an edge of the first recess may be overlapped on the side of the second color resist 2312 away from the base substrate 200 and the side of the third color resist 2313 away from the base substrate 200, so as to obtain a first color resist 2311 having a first curved surface after the exposure and development.

In the embodiments of the present disclosure, the semi-transparent mask plate with the gradient transmittance is used in the semi-transparent mask process, so that target structures with different thicknesses may be formed during the exposure and development. Specifically, in the embodiments of the present disclosure, a first color resist 2311 with a thick edge and a thin middle is formed to obtain the first curved surface. In the embodiments of the present disclosure, the transmittance of the semi-transparent mask plate may have a linear gradient transmittance or a nonlinear gradient transmittance. Optionally, the semi-transparent mask plate adopts the linear gradient transmittance, which may help to form a smooth first curved surface.

In some specific embodiments, a lens layer is formed on the first planarization layer, and the lens layer includes a plurality of lenses. For a specific structure of the lens, reference may be made to the aforementioned embodiments, which will not be repeated here.

It will be noted that, for detailed description of the embodiments of the present disclosure, reference may be made to the aforementioned embodiments, which will not be repeated here.

It will also be noted that the structures and manufacture processes shown in the embodiments of the present disclosure are just illustrative examples. In practical process, the corresponding structures may be changed and the patterning processes may be added or reduced as needed. For example, the length of the microcavity structure mentioned above may be the same or different. For example, in the process of forming the reflective electrode F in the display area, a respective pad may be formed in a bonding region, which is not specifically limited in the present disclosure.

At least some embodiments of the present disclosure further provide a display panel. FIG. 23 schematically shows a schematic diagram of a display panel according to the embodiments of the present disclosure. Referring to FIG. 23, the display panel includes the display substrate as described above. The display panel has a display area, a peripheral area, and related structures therein. For example, the display panel may be a liquid crystal display panel or an OLED display panel.

It will be understood that the display panel according to the embodiments of the present disclosure has all the characteristics and advantages of the above-mentioned display substrate. The details may be referred to the above descriptions and will not be repeated here.

At least some embodiments of the present disclosure further provide a display device. The display device may include any device or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as a head-mounted apparatus, electronic clothing, electronic bracelet, electronic necklace, electronic accessory, electronic tattoo, or smart watch), a television, etc.

It will be understood that the display device according to the embodiments of the present disclosure has all the characteristics and advantages of the above-mentioned display panel. The details may be referred to the above descriptions and will not be repeated here.

Although some embodiments of the general technical concept of the present disclosure have been illustrated and explained, those ordinary skilled in the art may understand that changes may be made to those embodiments without departing from the principle and spirit of the general technical concept. The scope of the present disclosure is defined by the claims and their equivalents.

1. A display substrate, comprising:
a base substrate;
a light emitting functional layer provided on the base substrate;
a color resist layer provided on a side of the light emitting functional layer away from the base substrate; and
a first planarization layer provided on a side of the color resist layer away from the base substrate,
wherein the light emitting functional layer comprises a plurality of light emitting devices, and the plurality of light emitting devices comprise a first light emitting device;
wherein the color resist layer comprises a plurality of color resists, different color resists allow light of different colors to pass through, and the plurality of color resists comprise a first color resist, a refractive index of the first color resist being greater than a refractive index of the first planarization layer; and
wherein the first color resist comprises a first light transmitting portion, a surface of the first light transmitting portion on a side close to the first planarization layer comprises a first curved surface recessed towards the base substrate, and an orthographic projection of the first light emitting device on the base substrate falls within an orthographic projection of the first light transmitting portion on the base substrate.

2. The display substrate according to claim 1, wherein the first color resist overlaps with other color resists adjacent to the first color resist, and in a region of an overlap between the first color resist and the other color resists adjacent to the first color resist, the first color resist is on a side of the other color resists away from the base substrate.

3. The display substrate according to claim 2, wherein the first color resist comprises a first edge portion surrounding the first light transmitting portion, a surface of the first edge portion on a side close to the first planarization layer comprises a second curved surface recessed towards the base substrate, and a curvature radius of the first curved surface is greater than a curvature radius of the second curved surface.

4. The display substrate according to claim 3, wherein the other color resists comprise a second color resist and a third color resist, and the second color resist comprises a second light transmitting portion and a second edge portion surrounding the second light transmitting portion;
wherein the first edge portion overlaps with the second edge portion, the second edge portion comprises a first portion, and the first edge portion is on a side of the first portion of the second edge portion away from the base substrate; and
wherein the third color resist is on a side of the second color resist away from the first color resist, and the second edge portion comprises a second portion on a side of the third color resist away from the base substrate.

5. The display substrate according to claim 4, wherein in a direction from the first color resist to the second color resist, an overlap between the first edge portion and the first portion has a first overlapping size;
wherein in a direction from the second color resist to the third color resist, an overlap between the second portion and the third color resist has a second overlapping size; and
wherein the first overlapping size is greater than or equal to the second overlapping size.

6. The display substrate according to claim 4, wherein an average thickness of either the second color resist or the third color resist is greater than an average thickness of the first color resist, and a difference between the average thickness of either the second color resist or the third color resist and the average thickness of the first color resist is a first predetermined difference, and a ratio of the first predetermined difference to the average thickness of either the second color resist or the third color resist is less than or equal to 1:5.

7. The display substrate according to claim 1, further comprising:
a lens layer provided on a side of the first planarization layer away from the base substrate,
wherein the lens layer comprises a plurality of lenses, and a first gap is formed between two lenses adjacent to each other; and
wherein an orthographic projection of the first gap on the base substrate at least partially overlaps with an orthographic projection of an overlap between color resists adjacent to each other on the base substrate.

8. The display substrate according to claim 7, wherein the orthographic projection of the first gap on the base substrate covers the orthographic projection of the overlap between the color resists adjacent to each other on the base substrate.

9. The display substrate according to claim 7, wherein the first gap comprises a groove recessed towards a center of a respective lens, the groove comprises a first surface on a side away from the base substrate, and the first surface comprises a flat surface or a smooth curved surface.

10. The display substrate according to claim 9, wherein in the first gap, the groove is recessed towards a center of each of the two lenses adjacent to each other, and comprises two first surfaces adjacent to each other on the side away from the base substrate, configured such that edges of the two first surfaces away from the base substrate are spaced apart from each other by a first predetermined spacing, edges of the two first surfaces close to the base substrate are spaced apart from each other by a second predetermined spacing, and the first predetermined spacing is less than the second predetermined spacing.

11. The display substrate according to claim 10, wherein the first overlapping size is less than the second predetermined spacing.

12. The display substrate according to claim 10, wherein a spacing between a center of the first curved surface and a surface of the first planarization layer away from the base substrate in a direction perpendicular to the base substrate is greater than or equal to the first predetermined spacing.

13. The display substrate according to claim 10, wherein at least one of the first surfaces has a first length in a direction from an edge of the first surface away from the base substrate to an edge of the first surface close to the base substrate, and the first length is less than the first predetermined spacing; and
wherein the at least one of the first surfaces has a first predetermined angle with the first planarization layer, and the first predetermined angle is an acute angle.

14. The display substrate according to claim 10, wherein the second predetermined spacing is less than a size of at least one lens in a thickness direction of the display substrate.

15. (canceled)

16. The display substrate according to claim 7, wherein at least one lens is coaxially arranged with the first curved surface and the first light emitting device:
wherein an orthographic projection of at least one lens on the base substrate falls within an orthographic projection of the first curved surface on the base substrate;
wherein a spacing between a center of the first curved surface and a surface of the first planarization layer away from the base substrate in a direction perpendicular to the base substrate is less than or equal to a maximum height of at least one lens; and
wherein the first gap comprises a third curved surface recessed towards the base substrate on a side close to the base substrate, and a curvature radius of the third curved surface is smaller than a curvature radius of the first curved surface.

17-19. (canceled)

20. The display substrate according to claim 1, further comprising an encapsulation layer between the light emitting functional layer and the color resist layer,
wherein the encapsulation layer comprises at least one fourth curved surface on a side close to the color resist layer, an orthographic projection of the at least one fourth curved surface on the base substrate at least partially overlaps with an orthographic projection of the first color resist on the base substrate, and the fourth curved surface and the encapsulation layer are configured such that, for incident light incident on the first color resist through the fourth curved surface, a brightness-related viewing angle after the incident light is incident on the first color resist is greater than a brightness-related viewing angle before the incident light is incident on the first color resist;
wherein the fourth curved surface comprises a curved surface recessed towards the base substrate, and the refractive index of the first color resist is less than a refractive index of the encapsulation layer; or wherein the fourth curved surface comprises a curved surface protruding towards the first planarization layer, and the refractive index of the first color resist is greater than the refractive index of the encapsulation layer; and
wherein the orthographic projection of the at least one fourth curved surface on the base substrate falls within an orthographic projection of the first curved surface on the base substrate.

21-22. (canceled)

23. The display substrate according to claim 3, wherein a ratio of a light emission area of the first light emitting device to an area of an orthographic projection of the first curved surface on the base substrate is greater than or equal to 1:2; and
wherein in a direction from a center of the first color resist to an edge of the first color resist, a ratio of a size of the first edge portion to a size of the first light transmitting portion is greater than or equal to 1:10.

24. (canceled)

25. A method of manufacturing a display substrate, comprising:
forming a base substrate;
forming a light emitting functional layer on the base substrate, wherein the light emitting functional layer comprises a plurality of light emitting devices, and the plurality of light emitting devices comprise a first light emitting device;
forming a color resist layer on a side of the light emitting functional layer away from the base substrate, wherein the color resist layer comprises a plurality of color resists, different color resists allow light of different colors to pass through, the plurality of color resists comprise a first color resist, a surface of the first color resist on a side away from the base substrate comprises a first curved surface recessed towards the base substrate, the first curved surface comprises a first light transmitting portion, and an orthographic projection of the first light emitting device on the base substrate falls within an orthographic projection of the first light transmitting portion on the base substrate; and
forming a first planarization layer on a side of the color resist layer away from the base substrate, a refractive index of the first color resist being greater than a refractive index of the first planarization layer.

26. The manufacturing method according to claim 25, wherein other color resists other than the first color resist in the color resist layer comprise a second color resist and a third color resist, and the forming the color resist layer on a side of the light emitting functional layer away from the base substrate comprises:
forming the second color resist and the third color resist on the side of the light emitting functional layer away from the base substrate by using a spin-coating process, wherein the second color resist and the third color resist adopt a first coating thickness;
forming a first color resist material on the side of the light emitting functional layer away from the base substrate;
spin-coating the first color resist material according to a second coating thickness less than the first coating thickness, wherein the second coating thickness is configured such that in a process of the spin-coating, the first color resist material between the second color resist and the third color resist forms a first recess, and an edge of the first recess is overlapped on a side of the second color resist away from the base substrate and a side of the third color resist away from the base substrate; and
retaining the first recess by exposure and development, so as to obtain the first color resist having the first curved surface.

27. A display device, comprising the display substrate of claim 1.
